(19) United States
(12) Patent Application Publication
(10) Pub. No.: US 2025/0275149 A1
(43) Pub. Date: Aug. 28, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: JUHYUNG KIM, Suwon-si (KR)

(21) Appl. No.: 18/797,745

(22) Filed: Aug. 8, 2024

(30) Foreign Application Priority Data
Feb. 28, 2024 (KR) 10-2024-0028792

(51) Int. Cl. H10B 51/20; H01L 21/28; H01L 25/065; H01L 29/51; H01L 29/78; H10B 51/10; H10B 80/00

(52) U.S. Cl. CPC H10B 51/20; H01L 25/0652; H10B 51/10; H10B 80/00; H10D 30/701; H10D 64/033; H10D 64/689; H01L 2225/06506

(57) ABSTRACT

Provided are semiconductor devices and electronic systems including the same. Semiconductor devices provided herein include a gate stacking structure that includes a plurality of gate electrodes and a plurality of cell insulation layers alternately stacked, and a channel structure that extends to pass through the gate stacking structure and includes a channel layer and a ferroelectric layer. The ferroelectric layer is between the plurality of gate electrodes and the channel layer and includes a first side surface and a second side surface that are opposite to one another. The first side surface of the ferroelectric layer and the second side surface of the ferroelectric layer are different from one another in at least one property selected from material, composition, grain size, crystal structure, coercive electric field, remnant polarization, and dielectric constant. Electronic systems provided herein include a main substrate, a semiconductor device on the main substrate, and a controller on the main substrate that is electronically connected to the semiconductor device. The semiconductor device may be as provided.

### CROSS-REFERENCE TO RELATED APPLICATION

This U.S. non-provisional application claims priority under 35 U.S.C. § 119 to and the benefit of Korean Patent Application No. 10-2024-0028792 filed in the Korean Intellectual Property Office on Feb. 28, 2024, the entire contents of which are incorporated herein by reference.

### BACKGROUND

The present disclosure relates to semiconductor devices and electronic systems including the same. More particularly, the present disclosure relates to semiconductor devices having an enhanced structure and electronic systems including the same.

In an electronic system implementing data storage, semiconductor devices capable of storing high-capacity data are in demand.

A method for increasing a data storage capacity of a semiconductor device has been researched. As one method for increasing the data storage capacity of a semiconductor device, a semiconductor device including three-dimensionally arranged memory cells instead of two-dimensionally arranged memory cells has been proposed.

### SUMMARY

The present disclosure provides semiconductor devices capable of enhancing performance, and electronic systems including the same.

A semiconductor device according to an embodiment includes a gate stacking structure that includes a plurality of gate electrodes, and a plurality of cell insulation layers, in which the plurality of gate electrodes and the plurality of cell insulation layers are alternately stacked, and a channel structure that extends to pass through the gate stacking structure, in which the channel structure includes a channel layer and a ferroelectric layer. The ferroelectric layer is between the plurality of gate electrodes and the channel layer and includes a first side surface and a second side surface that are opposite to one another, the first side surface being positioned adjacent to the channel layer and the second side surface being positioned adjacent to a gate electrode among the plurality of gate electrodes. The first side surface of the ferroelectric layer and the second side surface of the ferroelectric layer are different from one another in at least one property selected from material, composition, grain size, crystal structure, coercive electric field, remnant polarization, and dielectric constant.

A semiconductor device according to an embodiment includes a gate electrode, and a channel structure that extends to pass through the gate electrode. The channel structure includes a channel layer and a ferroelectric layer. The gate electrode surrounds a circumference of the channel structure. The ferroelectric layer includes a first side surface and a second side surface that are opposite to one another lengthwise in a direction of the channel structure, in which the ferroelectric layer is between the gate electrode and the channel layer. The first side surface may be positioned at the channel layer and the second side surface may be positioned at the gate electrode, with one or more optional layers or other components therebetween. In example embodiments, the first side surface of the ferroelectric layer and the second side surface of the ferroelectric layer are different from one another in coercive electric field.

An electronic system according to an embodiment includes a main substrate, which may be a package substrate, a semiconductor device on the main substrate, and a controller that is disposed on the main substrate and is electrically connected to the semiconductor device. The semiconductor device includes for example, a semiconductor device provided herein. An example semiconductor device includes a gate stacking structure that includes a plurality of gate electrodes, and a plurality of cell insulation layers, in which the plurality of gate electrodes and the plurality of cell insulation layers are alternately stacked, and a channel structure that extends to pass through the gate stacking structure, in which the channel structure includes a channel layer and a ferroelectric layer. The ferroelectric layer is between the plurality of gate electrodes and the channel layer and includes a first side surface and a second side surface that are opposite to one another. The first side surface of the ferroelectric layer may be positioned adjacent to the channel layer and the second side surface of the ferroelectric layer may be positioned adjacent to a gate electrode, optionally with one or more components or layers therebetween. In example embodiments, the first side surface of the ferroelectric layer and the second side surface of the ferroelectric layer are different from one another in at least one property selected from material, composition, grain size, crystal structure, coercive electric field, remnant polarization, and dielectric constant.

According to an embodiment, a first side surface and a second side surface of a ferroelectric layer may have different properties or different mechanical properties, and thus, a performance deterioration that may occur due to undesirable phenomena (e.g., a disturbance phenomenon or an under-program phenomenon) in an operation of a semiconductor device may be prevented. More particularly, in the semiconductor device that includes the ferroelectric layer and has a vertical structure or a 3-dimensional structure and may have an electric field difference due to an electric field concentration, the performance deterioration in the operation of the semiconductor device may be prevented. Accordingly, the performance of the semiconductor device may be enhanced.

### BRIEF DESCRIPTION OF THE DRAWINGS

FIG. 1 is a partial cross-sectional view that schematically illustrates a semiconductor device according to an embodiment.

FIG. 2 is an enlarged partial cross-sectional view that illustrates an example of a channel structure included in the semiconductor device illustrated in FIG. 1.

FIG. 3 is a partial cross-sectional view that illustrates a portion of a memory cell structure included in the semiconductor device illustrated in FIG. 1.

FIG. 4 is a partial plan view that illustrates a portion of the memory cell structure included in the semiconductor device illustrated in FIG. 1.

FIG. 5 illustrates a hysteresis loop of a ferroelectric material.

FIG. 6 is a graph that illustrates an electric field in a ferroelectric layer according to a distance from a center of the channel structure included in the semiconductor device illustrated in FIG. 1.

FIG. 7 is a partial cross-sectional view that illustrates a portion of a memory cell structure included in a semiconductor device according to an embodiment.

FIG. 8 is a partial cross-sectional view that illustrates a portion of a memory cell structure included in a semiconductor device according to an embodiment.

FIG. 9 is a graph that illustrates an electric field in a ferroelectric layer according to a distance from a center of a channel structure included in the semiconductor device illustrated in FIG. 8.

FIG. 10 is a partial cross-sectional view that illustrates a portion of a memory cell structure included in a semiconductor device according to an embodiment.

FIG. 11 is a partial cross-sectional view that illustrates a portion of a memory cell structure included in a semiconductor device according to an embodiment.

FIG. 12 is a partial cross-sectional view that illustrates a portion of a memory cell structure included in a semiconductor device according to an embodiment.

FIG. 13 is a partial cross-sectional view that illustrates a portion of a memory cell structure included in a semiconductor device according to an embodiment.

FIG. 14 is a cross-sectional view that illustrates a semiconductor device according to an embodiment.

FIG. 15 schematically illustrates an electronic system that includes a semiconductor device according to an embodiment.

FIG. 16 is a perspective view that schematically illustrates an electronic system including a semiconductor device according to an embodiment.

FIG. 17 is a cross-sectional view that schematically illustrates a semiconductor package according to an embodiment.

FIG. 18 is a cross-sectional view that schematically illustrates a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiment provided herein. Items described in the singular herein may be provided in plural. Thus, the description of a single item that is provided in plural should be understood to be applicable to the remaining plurality of items unless context indicates otherwise.

To clearly describe the present disclosure, parts or portions of certain features may be omitted, but may be present. The same or similar components or constituent elements are denoted by the same reference numerals throughout the present specification.

Further, because a size and/or a thickness of a portion, a region, a member, a unit, a layer, a film, a substrate, or other elements illustrated in the accompanying drawings may be arbitrarily illustrated for better understanding and convenience of explanation, the present disclosure is not limited to the illustrated size and/or thickness. In the drawings, thicknesses of portions, regions, members, units, layers, films, etc. may be enlarged or exaggerated for convenience of explanation and/or simple illustration, and are not intended to be limiting.

It will be understood that when a component such as a portion, a region, a member, a unit, a layer, a film, a substrate, or other element is referred to as being “on” another component, it may be directly on another component, or an intervening component may also be present. In contrast, when a component is referred to as being “directly on” another component, there is no intervening component present. Further, when a component is referred to as being “on” or “above” a reference component, a component may be positioned on or below the reference component, and is not necessarily “on” or “above” the reference component toward an opposite direction of gravity.

In addition, throughout the specification, unless explicitly described to the contrary, the word “comprise”, “include”, or “contain”, and variations such as “comprises”, “comprising”, “includes”, or “including” will be understood to imply the inclusion of other components rather than the exclusion of any other components.

Further, throughout the specification, the phrases “plan view”, “on a plan view”, or “in a plan view” may indicate a case where a portion is viewed from above or a top portion, and a phrase “on a cross-section” or “in a cross-sectional view” may indicate when a cross-section taken along a vertical direction is viewed from a side.

Terms such as “same,” or “similar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

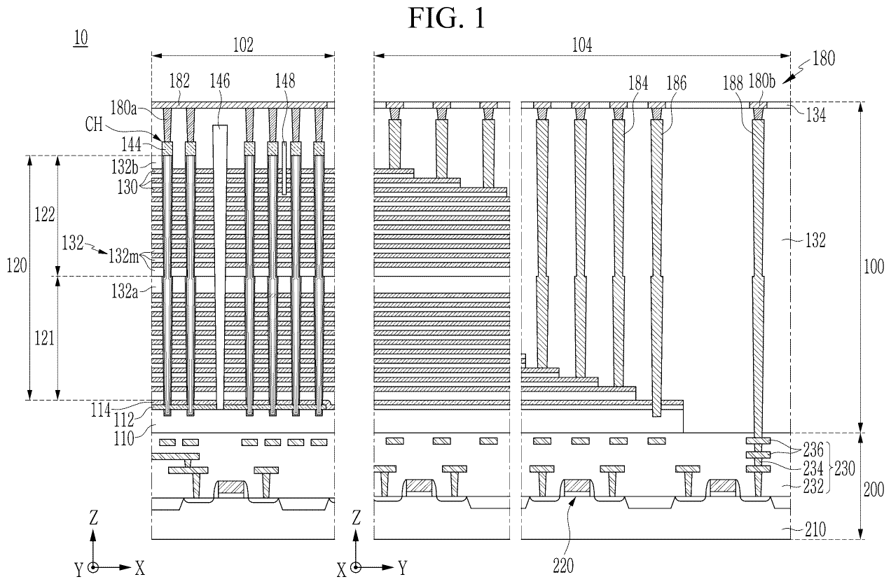

With reference to FIG. 1 to FIG. 6, a semiconductor device 10 according to an embodiment will be described in detail.

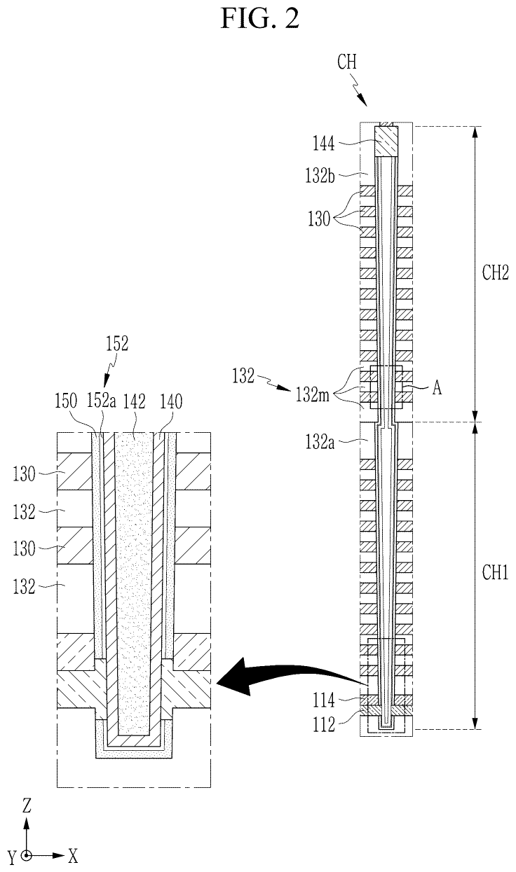

FIG. 1 is a partial cross-sectional view that schematically illustrates a semiconductor device 10 according to an embodiment. FIG. 2 is an enlarged partial cross-sectional view that illustrates an example of a channel structure CH included in the semiconductor device 10 illustrated in FIG. 1. For a clear understanding, coordinates of FIG. 1 are illustrated based on a cell array region 100, and a circuit region 200 is schematically illustrated regardless of coordinates. For a clear understanding, a gate contact portion 184, a source contact portion 186, and an input/output connection wiring 188 are illustrated in FIG. 1. Positions of the gate contact portion 184, the source contact portion 186, and the input/output connection wiring 188 may be variously modified within the scope of the present embodiments.

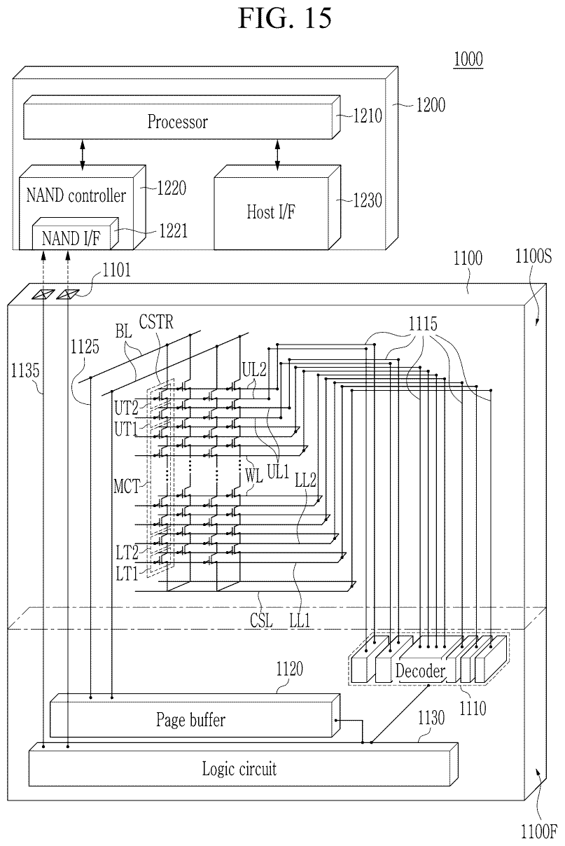

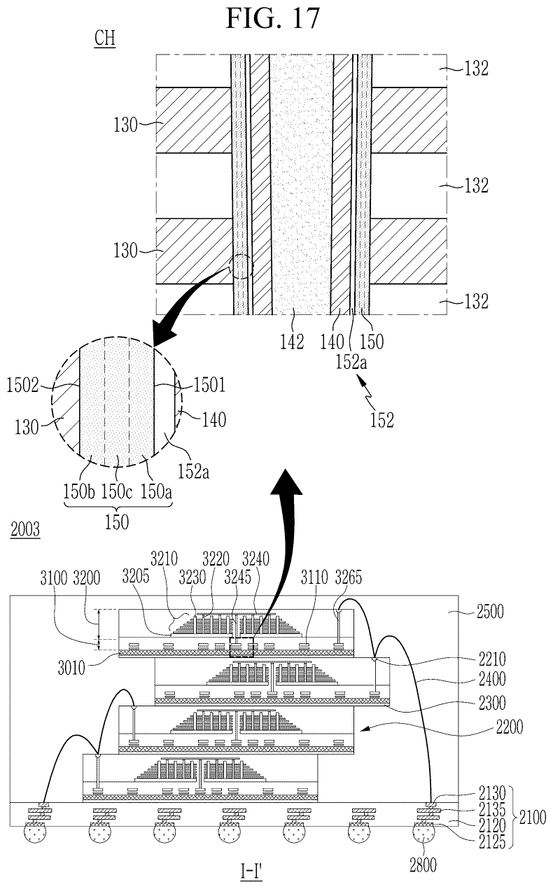

Referring to FIG. 1 and FIG. 2, a semiconductor device 10 according to an embodiment may include a cell region 100 that includes a memory cell structure and a circuit region 200 that includes a peripheral circuit structure for controlling an operation of the memory cell structure. For example, the circuit region 200 and the cell region 100 may correspond to a first structure 1100F and a second structure 1100S of a semiconductor device 1100 that is included in an example electronic system 1000 illustrated in FIG. 15, respectively. For example, the circuit region 200 and the cell region 100 may be portions that include a first structure 4100 and a second structure 4200 of a semiconductor chip 2200 illustrated in FIG. 17, respectively.

In an embodiment, the cell region 100 may be on the circuit region 200. Accordingly, an area corresponding to the circuit region 200 does not need to be secured separately from the cell region 100. Therefore, an area of the semiconductor device 10 may be reduced. However, the embodiments are not limited thereto. The circuit region 200 may be next to the cell region 100. Other various modifications are possible.

The circuit region 200 may include a first substrate 210, and a circuit element 220 and a first wiring portion 230 that are disposed on the first substrate 210.

The first substrate 210 may be a semiconductor substrate that includes a semiconductor material. For example, the first substrate 210 may be a semiconductor substrate that includes or is formed of a semiconductor material or may be a semiconductor substrate in which a semiconductor layer is on a base substrate. For example, the first substrate 210 may include single-crystalline or polycrystalline silicon, epitaxial silicon, germanium, silicon-germanium, silicon on insulator (SOI), germanium on insulator (GOI), and the like.

The circuit element 220 that is disposed on the first substrate 210 may include any of various circuit elements. For example, the circuit element 220 may constitute the peripheral circuit structure such as a decoder circuit 1110 (refer to FIG. 15), a page buffer 1120 (refer to FIG. 15), a logic circuit 1130 (refer to FIG. 15), and the like.

The circuit element 220 may include a transistor, but the embodiments are not limited thereto. For example, the circuit element 220 may include not only an active element such as the transistor but also a passive element such as a capacitor, a resistor, an inductor, and the like.

The first wiring portion 230 that is disposed on the first substrate 210 may be electrically connected to the circuit element 220. In an embodiment, the first wiring portion 230 may include a plurality of wiring layers 236 that are spaced apart from one another while interposing an insulation layer 232 therebetween and are electrically connected by a contact via 234 to form a desired path. The wiring layer 236 or the contact via 234 may include any of various conductive materials, and the insulation layer 232 may include any of various insulating materials. For example, among the plurality of wiring layers 236, an uppermost wiring layer 236 may include or constitute a pad to which a gate contact portion 184, a source contact portion 186, or an input/output connection wiring 188, is connected.

The cell region 100 may include a cell array region 102 and a connection region 104. The cell region 100 may include a gate stacking structure 120 and a channel structure CH as a memory cell structure. The gate stacking structure 120 and/or the channel structure CH may be disposed at least in the cell array region 102. A structure that connects the memory cell structure to the circuit region 200 or an external circuit may be disposed in the cell array region 102 and/or the connection region 104.

In an embodiment, the second substrate 110 may include a semiconductor layer including a semiconductor material. For example, the second substrate 110 may be a semiconductor substrate that includes or is formed of a semiconductor material or may be a semiconductor substrate in which a semiconductor layer is on a base substrate. For example, the second substrate 110 may include or be formed of silicon, germanium, silicon-germanium, silicon on insulator, germanium on insulator, and the like. In this instance, the second substrate 110 may include an n-type semiconductor layer that includes an n-type dopant (such as phosphorus (P), arsenic (As), or other n-type dopant) and/or a p-type semiconductor layer that includes a p-type dopant (such as boron (B), gallium (Ga), or others). However, the embodiments are not limited to a material of the second substrate 110, a conductive type, a material, or the like of the dopant doped to the semiconductor layer of the second substrate 110.

The gate stacking structure 120 may include a plurality of cell insulation layers 132 and a plurality of gate electrodes 130 that are alternately stacked on a first surface (e.g., a front surface or an upper surface) of the second substrate 110. The channel structure CH may extend in an extension direction that crosses the second substrate 110 and passes through the gate stacking structure 120. For example, the extension direction of the channel structure CH may be a direction crossing the second substrate 110 (e.g., a vertical direction to the second substrate 110). The extension direction of the channel structure CH may be a Z-axis direction in the drawing.

In an embodiment, conductive layers such as horizontal conductive layers 112 and 114, which are depicted e.g., as horizontal for example in FIG. 1, but are not limited to such orientation, may be provided between the second substrate 110 and the gate stacking structure 120 in the cell array region 102. The horizontal conductive layers 112 and 114 may electrically connect (e.g., directly connect) the channel structure CH and the second substrate 110. The horizontal conductive layers 112 and 114 may include a first horizontal conductive layer 112 and/or a second horizontal conductive layer 114 that are sequentially on the second substrate 110. The first horizontal conductive layer 112 may act as a portion of a common source line of the semiconductor device 10. For example, the first horizontal conductive layer 112 may act as the common source line together with the second substrate 110.

The first and second horizontal conductive layers 112 and 114 may include a semiconductor material (e.g., polycrystalline silicon). For example, the first horizontal conductive layer 112 may include a polycrystalline silicon layer that includes a dopant. The embodiments are not limited thereto. The second horizontal conductive layer 114 may include a material (e.g., an insulating material) that is different from a material of the first horizontal conductive layer 112, or the second horizontal conductive layer 114 might not be provided.

The gate stacking structure 120 may be disposed on the second substrate 110 (e.g., on the first and second horizontal conductive layers 112 and 114 that are disposed on the second substrate 110). The gate stacking structure 120 may include the cell insulation layers 132 and the gate electrodes 130 alternately stacked with one another.

The cell insulation layer 132 may include an interlayer insulation layer 132m and an upper insulation layer 132a or 132b. The interlayer insulation layer 132m may be between two gate electrodes 130 that are adjacent to one another in each of a plurality of stacking portions 121 and 122. The upper insulation layers 132a and 132b may be at upper surfaces of the plurality of stacking portions 121 and 122, respectively. In an embodiment, thicknesses of the plurality of cell insulation layers 132 might not be the same. For example, a thickness of the upper insulation layer 132a or 132b may be greater than a thickness of the interlayer insulation layer 132m. However, the embodiments are not limited thereto. For simple illustration, it is illustrated as an example in FIG. 1 that the cell insulation layer 132 is provided as one without a boundary in the connection region 104. However, one or a plurality of insulation layers may be disposed to have any of various stacking structures in the connection region 104. A shape, a structure, or other properties of the cell insulation layer 132 may be variously modified in some embodiments.

The gate electrode 130 may include any of various conductive materials. For example, the gate electrode 130 may include a metal material (e.g., tungsten (W), copper (Cu), aluminum (Al), molybdenum (Mo), or other metal materials), polycrystalline silicon (e.g., doped polycrystalline silicon), metal nitride (e.g., titanium nitride (TiN), tantalum nitride (TaN), tungsten nitride (WN), and the like), or a combination thereof. The cell insulation layer 132 may include any of various insulating materials. For example, the cell insulation layer 132 may include silicon oxide, silicon nitride, silicon oxynitride, a low dielectric constant material that has a lower dielectric constant than silicon oxide, or a combination thereof.

The channel structure CH may include a channel layer 140, and a ferroelectric layer 150 and a ferroelectric layer 150. More particularly, the channel structure CH may include the channel layer 140, and an interfacial insulation layer 152 and the ferroelectric layer 150 that are disposed on the channel layer 140 between the gate electrode 130 and the channel layer 140. The channel structure CH may further include a core insulation layer 142 at an inside of the channel layer 140. In some embodiments, the core insulation layer 142 might not be provided. The channel structure CH may further include a channel pad 144 that is electrically connected to the channel layer 140. The channel pad 144 may cover an upper surface of the core insulation layer 142 and be electrically connected to the channel layer 140.

Each channel structure CH may form one memory cell string, and a plurality of channel structures CH may be spaced apart from one another to form rows and columns in a plan view. The channel structure CH may have a pillar shape (e.g., a circular cylinder shape). For example, in a cross-sectional view, the channel structure CH may have an inclined side surface so that a width of the channel structure CH decreases as the channel structure CH goes to the second substrate 110 according to a high aspect ratio. However, present embodiments are not limited thereto, and an arrangement, a structure, a shape, or so on of the channel structure CH may be variously modified and be within the scope of the present application.

The channel layer 140 may include a semiconductor material (e.g., polycrystalline silicon). More particularly, the channel layer 140 may include a doped or undoped semiconductor material (e.g., doped or undoped polycrystalline silicon). In some embodiments, the channel layer 140 may include an oxide semiconductor material or a two-dimensional semiconductor material. For example, the channel layer 140 may include zinc oxide (ZnOx), zinc oxynitride (ZnONx), tin oxide (SnOx), zinc tin oxide (ZTO), indium oxide (InOx), indium zinc oxide (IZO), indium gallium zinc oxide (IGZO), indium gallium silicon oxide (IGSO), titanium oxide (TiOX), or other metal oxides, or may include a material that includes the above material and further includes a dopant. For example, the dopant may include at least one element selected from magnesium (Mg), zirconium (Zr), hafnium (Hf), tin (Sn), aluminum (Al), silicon (Si), and gallium (Ga). For example, the channel layer 140 may include an n-type oxide semiconductor material, but the embodiments are not limited thereto. A material of the channel layer 140 may be modified.

The core insulation layer 142 may include any of various insulating materials. For example, the core insulation layer 142 may include silicon oxide, silicon nitride, silicon oxynitride, or a combination thereof. The channel pad 144 may be electrically connected to the channel layer 140. The channel pad 144 may include a conductive material (e.g., polycrystalline or single-crystalline silicon doped with a dopant). However, the embodiments are not limited to a structure, a material, and the like of the channel layer 140, the core insulation layer 142, or the channel pad 144.

The ferroelectric layer 150 may be formed of or include a ferroelectric (FE) material.

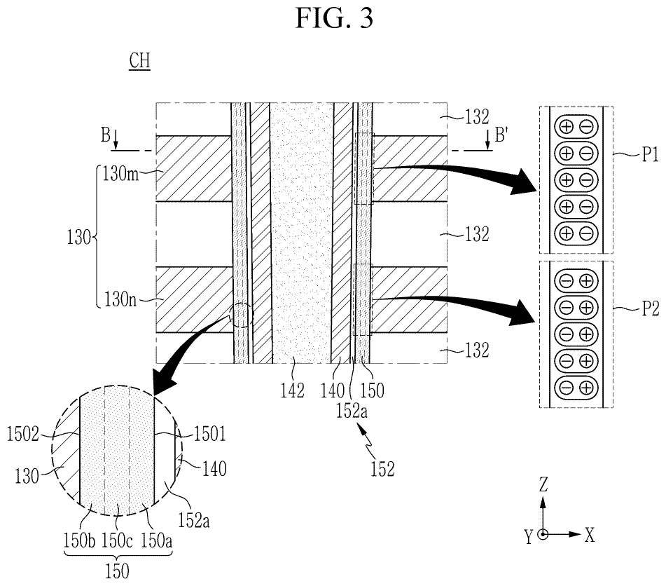

The ferroelectric material may maintain remnant polarization due to dipoles without an externally applied electric field and thus data may be stored in the ferroelectric material non-volatilely. A polarization direction in the ferroelectric material may be changed by an externally applied electric field. Data may be stored in the ferroelectric layer 150 by using the property of the ferroelectric layer 150. An operation method of the semiconductor device 10 (e.g., a ferroelectric memory device) that includes the memory cell structure including the ferroelectric layer 150 will be described in detail later with reference to FIG. 3.

In an embodiment, the ferroelectric layer 150 may include at least one of hafnium (Hf), zirconium (Zr), silicon (Si), yttrium (Y), aluminum (Al), gadolinium (Gd), strontium (Sr), lanthanum (La), titanium (Ti), or scandium (Sc), or an oxide including the above material. For example, the ferroelectric layer 150 may include a base material doped with a dopant. The base material may include at least one of hafnium oxide, zirconium oxide, or hafnium-zirconium oxide, and at least a portion of the ferroelectric layer 150 may include the base material and a dopant. In this instance, the dopant may include hafnium, zirconium, silicon, yttrium, aluminum, gadolinium, strontium, lanthanum, titanium, scandium, carbon (C), germanium (Ge), tin (Sn), lead (Pb), magnesium (Mg), calcium (Ca), barium (Ba), zinc (Zn), nitrogen (N), or tantalum (Ta), or a combination thereof. For example, the base material of the ferroelectric layer 150 may include or be formed of the hafnium oxide.

In an example embodiment, a material of the ferroelectric layer 150 is not limited to the examples above, and the ferroelectric layer 150 may include any of various ferroelectric materials. In an embodiment, the ferroelectric layer 150 may include a ferroelectric material that has a crystalline structure (e.g., a ferroelectric material that has an orthorhombic crystal structure or a perovskite structure). For example, the ferroelectric layer 150 may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, or BaSrTiO₃, or a combination thereof.

The interfacial insulation layer 152 may compensate for a polarization charge of the ferroelectric layer 150 so that the remnant polarization of the ferroelectric layer 150 is stably maintained. In an embodiment, the interfacial insulation layer 152 may include silicon oxide (SiOx), silicon nitride (SiNx), silicon oxynitride (SiONx), aluminum oxide (AlOx), aluminum oxynitride (AlONx), hafnium oxide (HfO), a high dielectric constant material that has a higher dielectric constant than silicon oxide, or a combination thereof.

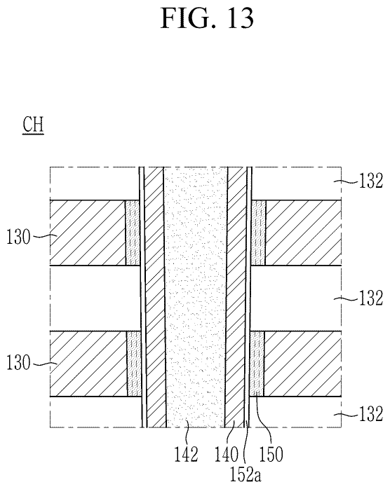

In FIG. 3 for example, it is illustrated as an example that the interfacial insulation layer 152 includes a first interfacial insulation layer 152a that extends in the extension direction of the channel structure CH or the vertical direction (the z-axis direction in the drawings) between the ferroelectric layer 150 and the channel layer 140. However, the interfacial insulation layer 152 may further include a second interfacial insulation layer 152b (refer to FIG. 13) or so on. The second interfacial insulation layer 152b will be described later in more detail with reference to FIG. 13.

In an embodiment, a material, a stacking structure, a position or so on of the ferroelectric layer 150 or the interfacial insulation layer 152 may be variously modified, and the embodiments are not limited thereto.

In an embodiment, the gate stacking structure 120 may include a plurality of stacking portions 121 and 122 that are sequentially stacked on the second substrate 110. Thereby, a number of stacked gate electrodes 130 may be increased and thus a number of memory cells may be increased with a stable structure. Accordingly, a data storage capacity of the semiconductor device 10 may be increased. In FIG. 1, it is illustrated as an example that the gate stacking structure 120 includes first and second stacking portions 121 and 122. However, the embodiments are not limited thereto. In some embodiments, the gate stacking structure 120 may include one stacking portion or three or more stacking portions.

When the plurality of stacking portions 121 and 122 are provided as in the above, the channel structure CH may include a plurality of channel portions CH1 and CH2 that respectively pass through the plurality of stacking portions 121 and 122. The plurality of channel portions CH1 and CH2 may be connected to one another. In a cross-sectional view, each of the plurality of channel portions CH1 and CH2 may have an inclined side surface such that a width of each of the plurality of channel portions CH1 and CH2 decreases toward the second substrate 110 according to an aspect ratio. A bent portion due to a difference in widths of the plurality of channel portions CH1 and CH2 may be provided at a connection portion of the plurality of channel structures CH1 and CH2. In some embodiments, the plurality of channel portions CH1 and CH2 may have an inclined side surface that is continuously extended without the bent portion. In FIG. 2, it is illustrated as an example that the interfacial insulation layer 152, the ferroelectric layer 150, the channel layer 140, or the core insulation layer 142 of the plurality of channel portions CH1 and CH2 continuously extend to have an integral structure. In some embodiments, the ferroelectric layers 150, the channel layers 140, or the core insulation layers 142 of the plurality of channel portions CH1 and CH2 may be separately formed and be electrically connected to one another. In some embodiments, a separate channel pad may be additionally disposed at the connection portion of the plurality of channel portions CH1 and CH2. The embodiments are not limited to a shape of the plurality of channel portions CH1 and CH2.

In an embodiment, the gate stacking structure 120 may be divided into a plurality of portions in a plan view by a separation structure 146. The separation structure 146 may extend in a direction (the Z-axis direction in the drawings) that cross the second substrate 110 or the vertical direction to pass through the gate stacking structure 120. An upper separation region 148 may be at an upper portion of the gate stacking structure 120. In a plan view, the separation structure 146 and/or the upper separation region 148 may extend in a first direction (a Y-axis direction in the drawings) that is an extension direction of the gate electrode 130. A plurality of separation structures 146 and/or a plurality of upper separation regions 148 may be spaced apart from one another at a predetermined interval in a second direction (a Y-axis direction in the drawings).

In a plan view, the plurality of gate stacking structures 120 may each extend in the first direction (the Y-axis direction of the drawing) and be spaced apart from one another at a predetermined interval in the second direction (the X-axis direction of the drawing) by the separation structure 146. The gate stacking structure 120 that is divided by the separation structure 146 may constitute one memory cell block. However, the embodiments are not limited thereto, and a range of the memory cell blocks is not limited thereto.

For example, the separation structure 146 may pass through the gate stacking structure 120 and extend to the second substrate 110, and the upper separation region 148 may separate one or a part of the plurality of gate electrodes 130. The upper separation region 148 may be disposed between the separation structures 146.

For example, in a cross-sectional view, the separation structure 146 may have an inclined side surface such that a width of the separation structure 146 gradually decreases toward the second substrate 110 due to a high aspect ratio. However, the embodiments are not limited thereto. A side surface of the separation structure 146 may extend vertically with respect to the second substrate 110, or the separation structure 146 may have a bent portion at the connection portion of the first and second stacking portions 121 and 122.

The separation structure 146 and/or the upper separation region 148 may be filled with any of various insulating materials. For example, the separation structure 146 or the upper separation region 148 may include an insulating material such as silicon oxide, silicon nitride, or silicon oxynitride. However, the embodiments are not limited thereto, and a structure, a shape, a material, or so on of the separation structure 146 or the upper separation region 148 may be modified.

The connection region 104 and the second wiring portion 180 may be provided to connect the gate stacking structure 120 and the channel structure CH in the cell array region 102 to the circuit region 200 or an external circuit. The connection region 104 may be at a periphery of the cell array region 102 and a portion of the second wiring portion 180 may be in the connection region 104.

In an embodiment, the second wiring portion 180 may include a member electrically connecting the gate electrode 130, the channel structure CH, and/or the second substrate 110 to the circuit region 200 or the external circuit. For example, the second wiring portion 180 may include a bit line 182, a gate contact portion 184, a source contact portion 186, an input/output connection wiring 188, a contact via 180a, and a connection wiring 180b. The contact via 180a may be connected to the bit line 182, the gate contact portion 184, the source contact portion 186, and/or the input/output connection wiring 188. The connection wiring 180b may be electrically connected to the bit line 182, the gate contact portion 184, the source contact portion 186, the input/output connection wiring 188, and/or the contact via 180a.

The bit line 182 may extend in the second direction (the X-axis direction in the drawings) that is transverse to or crosses the first direction. The bit line 182 may be electrically connected to the channel structure CH (e.g., the channel pad 144) through the contact via 180a (e.g., a bit line contact via) that pass through the cell insulation layer 132.

In the connection region 104, the plurality of gate electrodes 130 may extend in the first direction (the Y-axis direction in the drawings). Extension lengths of the plurality of gate electrodes 130 may sequentially decrease in a direction away from the second substrate 110. For example, the plurality of gate electrodes 130 may have a stair shape in one direction or a plurality of directions in the connection region 104. In the connection region 104, a plurality of gate contact portions 184 may pass through the cell insulation layer 132 to be electrically connected to the plurality of gate electrodes 130, respectively, that extend to the connection region 104.

The source contact portion 186 may be electrically connected to the horizontal conductive layers 112 and 114 and/or the second substrate 110 that constitutes at least a portion of a common source line. The input/output connection wiring 188 may be electrically connected to an input/output pad.

The connection wiring 180b may be disposed in the cell array area 102 and/or the connection area 104. The bit line 182, the gate contact portion 184, the source contact portion 186, and/or the input/output connection wiring 188 may be electrically connected to the connection wiring 180b. For example, the gate contact portion 184, the source contact portion 186, and/or the input/output connection wiring 188 may be electrically connected to the connection wiring 180b through the contact via 180a.

In FIG. 1, it is illustrated as an example that the connection wiring 180b is a single layer on the same plane as the bit line 182 and an additional insulation layer 134 is a single layer on the same plane as the bit line 182 and the connection wiring 180b. However, this is brief illustration for convenience. For an electrical connection with the bit line 182, the gate contact portion 184, the source contact portion 186, and/or the input/output connection wiring 188, the connection wiring 180b may include a plurality of wiring layers and may further include a contact via.

By the second wiring portion 180 and the first wiring portion 230, the bit line 182 that is connected to the channel structure CH, the gate electrode 130, the horizontal conductive layers 112 and 114, and/or the second substrate 110 may be electrically connected to the circuit element 220 of the circuit region 200.

In FIG. 1, it is illustrated as an example that the gate contact portions 184, the source contact portion 186, and/or the input/output connection wiring 188 has an inclined side surface such that a width of the gate contact portion 184, the source contact portion 186, and/or the input/output connection wiring 188 decreases toward the second substrate 110 due to an aspect ratio and a bent portion is provided at a boundary portion of the plurality of stacking portions 121 and 122 in a cross-sectional view. However, the embodiments are not limited thereto. In some embodiments, the gate contact portion 184, the source contact portion 186, and/or the input/output connection wiring 188 might not include the bent portion at the boundary portion of the plurality of stacking portions 121 and 122. Other various modifications are possible.

In an embodiment, the ferroelectric layer 150 may include a plurality of portions 150a, 150b, and 150c that have different properties or physical properties. This will be described in more detail with reference to FIG. 3 to FIG. 6.

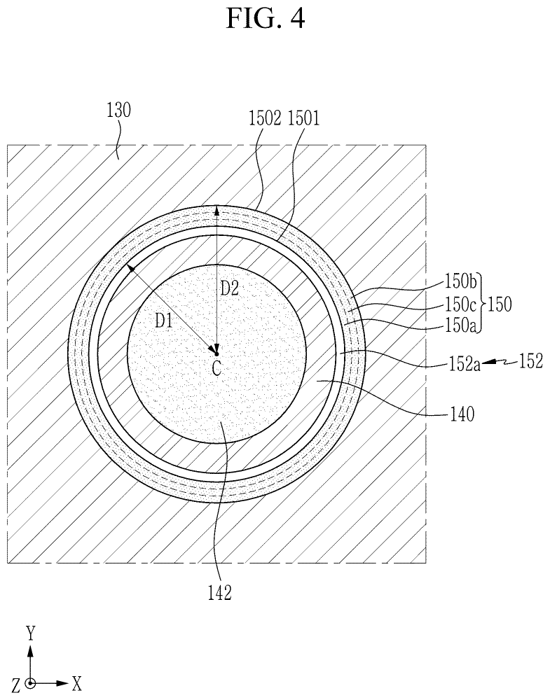

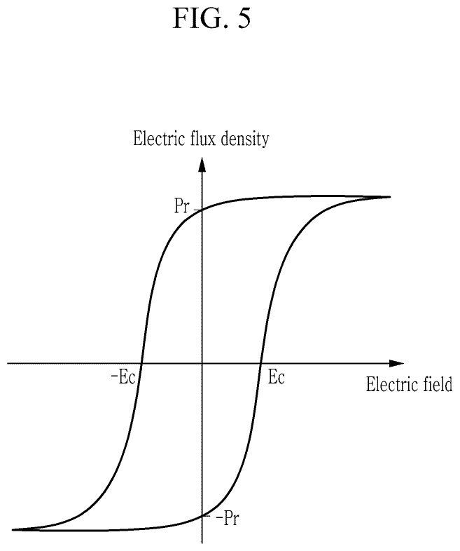

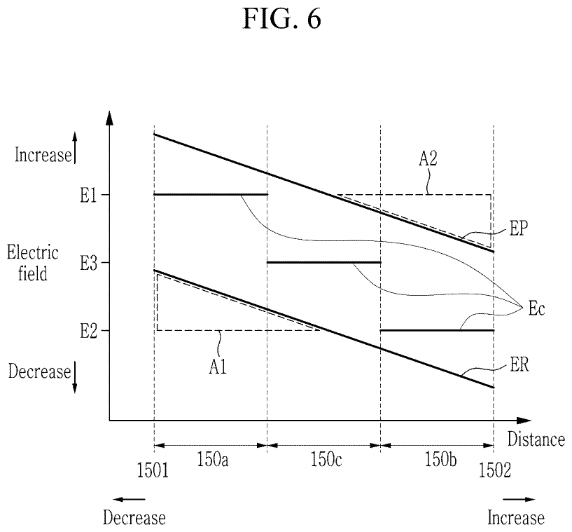

FIG. 3 is a partial cross-sectional view that illustrates a portion of the memory cell structure included in the semiconductor device 10 illustrated in FIG. 1. FIG. 4 is a partial plan view that illustrates a portion of the memory cell structure included in the semiconductor device 10 illustrated in FIG. 1. FIG. 3 illustrates a portion that corresponds to a portion A in FIG. 2, and FIG. 4 illustrates a plan view taken along a line B-B′ in FIG. 3. FIG. 5 illustrates a hysteresis loop of a ferroelectric material. FIG. 6 is a graph that illustrates an electric field in the ferroelectric layer 150 according to a distance from a center of the channel structure CH included in the semiconductor device 10 illustrated in FIG. 1. For comparison, a first area A1 and a second area A2 of comparative examples are illustrated as dotted lines in FIG. 6. In a comparative example where an entire portion of a ferroelectric layer has a second coercive electric field E2, a disturbance phenomenon may occur in the first area A1. The portion of a ferroelectric layer may correspond to a gate electrode. In another comparative example where an entire portion of a ferroelectric layer has a first coercive electric field E1, an under-program phenomenon may occur in the second area A2.

Referring to FIG. 3 and FIG. 4, in an embodiment, the ferroelectric layer 150 may include a first side surface 1501 and a second side surface 1502. The first side surface 1501 and the second side surface 1502 may be disposed between the plurality of gate electrodes 130 and the channel layer 140 and be opposite to one another. In example embodiments, as can be seen from a plan view, the gate electrode 130 may surround a circumference of the channel structure CH (the outer layer of which may be the ferroelectric layer 150). For example, as can be seen in a plan view, the gate electrode 130 may entirely surround the circumference of the channel structure CH (e.g., the ferroelectric layer 150). In this instance, the first side surface 1501 may be an inner side surface of the ferroelectric layer 150, and the second side surface 1502 may be an outer side surface of the ferroelectric layer 150.

More particularly, in a certain position in a thickness direction of the semiconductor device 10 (the Z-axis direction in the drawings), a distance between a center C of the channel structure CH and the first side surface 1501 of the ferroelectric layer 150 may be a first distance D1, and a distance between the center C of the channel structure CH and the second side surface 1502 of the ferroelectric layer 150 may be a second distance D2. In this example, the first distance D1 may be less than the second distance D2. The first distance D1 or the second distance D2 may refer to a shortest distance or an average distance.

An area of the first side surface 1501 of the ferroelectric layer 150 may be less than an area of the second side surface 1502 of the ferroelectric layer 150. For example, in a portion that corresponds to one gate electrode 130, an area of the first side surface 1501 of the ferroelectric layer 150 may be less than an area of the second side surface 1502 of the ferroelectric layer 150.

In a plan view, the first side surface 1501 may have a circular shape that has a radius of the relatively small first distance D1, and the second side surface 1502 may have a circular shape that has a radius of the relatively large second distance D2. In a plan view, the ferroelectric layer 150 may have an annular shape or a ring shape. However, the embodiments are not limited thereto. A plan view shape of the first side surface 1501 or the second side surface 1502 of the ferroelectric layer 150, or a plan view shape of the ferroelectric layer 150, may be variously modified. For example, a plan view shape of the first side surface 1501 or the second side surface 1502 of the ferroelectric layer 150, or a plan view shape of the ferroelectric layer 150, may be a polygonal shape.

In an embodiment, the first side surface 1501 of the ferroelectric layer 150 and the second side surface 1502 of the ferroelectric layer 150 may have different material, electrical, physical, or other properties. For example, the first side surface 1501 of the ferroelectric layer 150 and the second side surface 1502 of the ferroelectric layer 150 may be different from one another in at least one of material, composition, grain size, crystal structure (e.g., fraction of a crystal structure), or coercive electric field. In some embodiments, the first side surface 1501 of the ferroelectric layer 150 and the second side surface 1502 of the ferroelectric layer 150 may be different from one another in remnant polarization Pr or dielectric constant (K).

Referring to FIG. 5, the coercive electric field Ec may correspond to an electric field at which an electric flux density becomes zero (0) in the hysteresis loop of the ferroelectric material, and the remnant polarization Pr may correspond to an electric flux density at which an electric field becomes zero (0) in the hysteresis loop of the ferroelectric material. The coercive electric field may correspond to a critical electric field that may switch a polarization direction according to an applied voltage.

When a circumference or perimeter of the ferroelectric layer 150 is surrounded by a gate electrode 130, as can be seen in a plan view as in the above, a relatively large electric field may be applied to the first side surface 1501 compared to the second side surface 1502. This may be because the first side surface 1501 is relatively close to the center C of the channel structure CH and has a relatively small area, while the second side surface 1502 is relatively far away from the center C of the channel structure CH and has a relatively large area.

In an embodiment, a coercive electric field Ec of the first side surface 1501 of the ferroelectric layer 150 may be different from a coercive electric field Ec of the second side surface 1502 of the ferroelectric layer 150, and thus, a problem that may be caused by an electric field difference between the first side surface 1501 of the ferroelectric layer 150 and the second side surface 1502 of the ferroelectric layer 150 may be prevented. In this instance, a remnant polarization Pr or a dielectric constant in the first side surface 1501 of the ferroelectric layer 150 may be different from a remnant polarization Pr or a dielectric constant in the second side surface 1502 of the ferroelectric layer 150. By the difference in at least one of material, composition, grain size, or crystal structure between the first side surface 1501 of the ferroelectric layer 150 and the second side surface 1502 of the ferroelectric layer 150, the first side surface 1501 of the ferroelectric layer 150 and the second side surface 1502 of the ferroelectric layer 150 may be different from one another in coercive electric field Ec.

In this instance, the coercive electric field Ec of the first side surface 1501 of the ferroelectric layer 150 may be greater than the coercive electric field Ec of the second side surface 1502 of the ferroelectric layer 150. The remnant polarization Pr in the first side surface 1501 of the ferroelectric layer 150 may be less than the remnant polarization Pr in the second side surface 1502 of the ferroelectric layer 150. The dielectric constant in the first side surface 1501 of the ferroelectric layer 150 may be greater than the dielectric constant in the second side surface 1502 of the ferroelectric layer 150.

In an embodiment, the first side surface 1501 of the ferroelectric layer 150 includes a first material, and the second side surface 1502 of the ferroelectric layer 150 includes a second material, and the first material may be different from the second material. In example embodiments, a coercive electric field Ec of the first material in the first side surface 1501 of the ferroelectric layer 150 may be greater than a coercive electric field Ec of the second material in the second side surface 1502 of the ferroelectric layer 150. In example embodiments, a first dopant concentration of a first ferroelectric material in the first side surface 1501 of the ferroelectric layer 150 may be greater than a second dopant concentration of a second ferroelectric material in the second side surface 1502 of the ferroelectric layer 150. Thereby, the coercive electric field Ec of the first side surface 1501 of the ferroelectric layer 150 may be greater than the coercive electric field Ec of the second side surface 1502 of the ferroelectric layer 150.

For example, the second side surface 1502 of the ferroelectric layer 150 might not include the dopant, and the first side surface 1501 of the ferroelectric layer 150 may include the dopant. For example, in a case that at least a portion of the ferroelectric layer 150 includes silicon doped hafnium oxide (HSO) or zirconium doped hafnium oxide (HZO), the second side surface 1502 of the ferroelectric layer 150 might not include the dopant (e.g., silicon or zirconium), and the first side surface 1501 of the ferroelectric layer 150 may include the dopant (e.g., silicon or zirconium). However, the embodiments are not limited thereto, and the base material and/or the dopant of the ferroelectric layer 150 may be variously modified.

In some embodiments, each of the first side surface 1501 and the second side surface 1502 of the ferroelectric layer 150 includes the dopant, and a dopant concentration in the first side surface 1501 of the ferroelectric layer 150 may be greater than a dopant concentration in the second side surface 1502 of the ferroelectric layer 150. For example, in a case that the ferroelectric layer 150 include silicon doped hafnium oxide or zirconium doped hafnium oxide, a dopant concentration (e.g., a silicon or zirconium concentration) in the first side surface 1501 of the ferroelectric layer 150 may be greater than a dopant concentration (e.g., a silicon or zirconium concentration) in the second side surface 1502 of the ferroelectric layer 150. However, the embodiments are not limited thereto, and the base material and/or the dopant of the ferroelectric layer 150 may be variously modified.

In an embodiment, a second grain size in the second side surface 1502 of the ferroelectric layer 150 may be smaller than a first grain size in the first side surface 1501 of the ferroelectric layer 150. As used herein, the term “grain size” may also be referred to as a “domain size”. The first grain size in the first side surface 1501 may refer to an average grain size or an average domain size in the first side surface 1501, and the second grain size in the second side surface 1502 may refer to an average grain size or an average domain size in the second side surface 1502. According to example embodiments herein, coercive electric field Ec of the first side surface 1501 of the ferroelectric layer 150 may be greater than the coercive electric field Ec of the second side surface 1502 of the ferroelectric layer 150.

In an embodiment, the first side surface 1501 of the ferroelectric layer 150 and the second side surface 1502 of the ferroelectric layer 150 may be different from one another in crystal structure. The ferroelectric layer 150 may include a plurality of phases, each having a predetermined crystal structure. The phrase of “different in crystal structure” may refer to a case that is different in a fraction or a proportion of at least one phase among the plurality of phases. Here, the “fraction” or the proportion of one phase may refer to a volume fraction of one phase or a vol % of one phase relative to a total 100 vol % of the ferroelectric layer 150.

In this instance, the crystal structure in the first side surface 1501 of the ferroelectric layer 150 may be different from the crystal structure in the second side surface 1502 of the ferroelectric layer 150 so that the coercive electric field Ec of the first side surface 1501 of the ferroelectric layer 150 is greater than the coercive electric field Ec of the second side surface 1502 of the ferroelectric layer 150. For example, in a case that the ferroelectric layer 150 includes hafnium oxide as the base material, the ferroelectric layer 150 may include at least one of an orthorhombic phase, a tetragonal phase, a monoclinic phase, and or the like. In this instance, a fraction of an orthorhombic phase in the first side surface 1501 of the ferroelectric layer 150 may be different from a fraction of an orthorhombic phase in the second side surface 1502 of the ferroelectric layer 150. In non-limiting embodiments, a fraction of a tetragonal phase in the first side surface 1501 of the ferroelectric layer 150 may be different from a fraction of a tetragonal phase in the second side surface 1502 of the ferroelectric layer 150. In some embodiments, a fraction of a monoclinic phase in the first side surface 1501 of the ferroelectric layer 150 may be different from a fraction of a monoclinic phase in the second side surface 1502 of the ferroelectric layer 150.

According to example embodiments, the ferroelectric layer 150 includes at least one of an orthorhombic phase, a tetragonal phase, and a monoclinic phase. The first side surface of the ferroelectric layer may include a fraction of at least one phase selected from a first orthorhombic phase, a first tetragonal phase, and a first monoclinic phase, and the second side surface of the ferroelectric layer may include a fraction of at least one phase selected from a second orthorhombic phase, a second tetragonal phase, and a second monoclinic phase. The first side surface and the second side surface may be different from one other with respect to fraction of at least one of an orthorhombic phase, a tetragonal phase, and a monoclinic phase. For example, first side surface and the second side surface may be different from one other with respect to fraction of at least one phase selected from the group consisting of the first orthorhombic phase and the second orthorhombic phase, the first tetragonal phase and the second tetragonal phase, and the first monoclinic phase and the second monoclinic phase.

Fractions of the plurality of crystal structures or phases included in the ferroelectric layer 150 may be varied according to a composition of the ferroelectric layer 150, process conditions in a process of forming the ferroelectric layer 150, process conditions in a heat-treatment process performed after the process of forming the ferroelectric layer 150, or so on. Therefore, when a relationship that the coercive electric field Ec of the first side surface 1501 of the ferroelectric layer 150 is greater than the coercive electric field Ec of the second side surface 1502 of the ferroelectric layer 150 is satisfied, a fraction of at least one of the orthorhombic phase, the tetragonal phase, or the monoclinic phase in the first side surface 1501 of the ferroelectric layer 150 may be the same as or different from a fraction of at least one of the orthorhombic phase, the tetragonal phase, or the monoclinic phase in the second side surface 1502 of the ferroelectric layer 150.

In an embodiment, the first side surface 1501 of the ferroelectric layer 150 and the second side surface 1502 of the ferroelectric layer 150 may be different from one another in one or more of remnant polarization, dielectric constant, material, composition (e.g., dopant concentration), grain size, or crystal structure, and the coercive electric field Ec of the first side surface 1501 of the ferroelectric layer 150 may be greater than the coercive electric field Ec of the second side surface 1502 of the ferroelectric layer 150.

In an embodiment, the coercive electric field, the remnant polarization, the dielectric constant, or so on in the first side surface 1501 or the second side surface 1502 of the ferroelectric layer 150 may be inferred, predicted, or determined through analysis of the material, the composition, the grain size, the crystal structure (e.g., the fraction of the phase or the crystal structure), or so on in the first side surface 1501 or the second side surface 1502 of the ferroelectric layer 150. For example, the material, the composition, the grain size, the crystal structure (e.g., the fraction of the phase or the crystal structure), or so on in each position of the ferroelectric layer 150 may be analyzed through secondary ion mass spectroscopy (SIMS), Auger electron spectroscopy (AES), X-ray photoelectron spectroscopy (XPS), X-ray diffraction (XRD), transmission electron microscope (TEM), precession electron diffraction (PED) or so on.

In an embodiment, the ferroelectric layer 150 may include a plurality of portions 150a, 150b, and 150c that are different from one another in at least one of material, composition, grain size, crystal structure, and coercive electric field. That is, the ferroelectric layer 150 may have a multi-layered structure. Each of the material, the composition, the grain size, the crystal structure, and the coercive electric field of each of the plurality of portions 150a, 150b, and 150c may be substantially uniform. That is, each of the material, the composition, the grain size, the crystal structure, and the coercive electric field of the first portion 150a may be substantially uniform. Each of the material, the composition, the grain size, the crystal structure, and the coercive electric field of the second portion 150b may be substantially uniform. Each of the material, the composition, the grain size, the crystal structure, and the coercive electric field of the third portion 150c may be substantially uniform. The phrase of substantially uniform may include a case that is the same and a case that has a difference within an error range.

For example, the ferroelectric layer 150 may include a first portion 150a that includes the first side surface 1501, a second portion 150b that includes the second side surface 1502, and at least one third portion 150c that is disposed between the first portion 150a and the second portion 150b.

For example, the first portion 150a of the ferroelectric layer 150 may have a first coercive electric field E1, the second portion 150b of the ferroelectric layer 150 may have a second coercive electric field E2 that is less than the first coercive electric field E1, and the third portion 150b of the ferroelectric layer 150 may have a coercive electric field that is less than the first coercive electric field E1 and is greater than the second coercive electric field E2.

In the drawing, it is illustrated as an example that the third portion 150c includes a single portion that has the third coercive electric field E3. However, the embodiments are not limited thereto. The third portion 150c may include a plurality of portions, and a coercive electric field of the plurality of portions may decrease in stages from a portion close to the first portion 150a to a portion close to the second portion 150b. In some embodiments, the coercive electric field of the third portion 150c may gradually decrease from the portion close to the first portion 150a to the portion close to the second portion 150b. Other various modifications are possible.

In an embodiment, as can be seen in a plan view, a gate electrode 130 may surround a circumference or perimeter of the channel structure CH (the outer layer of which may be the ferroelectric layer 150), and thus, an electric field in a portion close to the center C of the channel structure CH may be greater than an electric field in a portion far away from the center C of the channel structure CH. For example, a program electric field EP that is generated by a voltage applied in a program operation may decrease from the first side surface 1501 of the ferroelectric layer 150 to the second side surface 1502 of the ferroelectric layer 150, and a read electric field ER that is generated by a voltage applied in a read operation may decrease from the first side surface 1501 of the ferroelectric layer 150 to the second side surface 1502 of the ferroelectric layer 150. FIG. 6 illustrates as an example that the program electric field EP or the read electric field ER may gradually decrease from the first side surface 1501 of the ferroelectric layer 150 to the second side surface 1502 of the ferroelectric layer 150 to have a linear shape. However, the embodiments are not limited thereto. The shape in which the program electric field EP or the read electric field ER decreases from the first side surface 1501 of the ferroelectric layer 150 to the second side surface 1502 of the ferroelectric layer 150 may be variously modified. An erase electric field that is generated by a voltage applied in an erase operation may have a shape that is the same as or similar to the shape of the read electric field ER.

In an embodiment, the first portion 150a that is close to the first side surface 1501 to which a relatively large electric field is applied may have the relatively large first coercive electric field E1. In this instance, the first coercive electric field E1 may be less than a program electric field EP applied to the first portion 150a, and be greater than a read electric field ER or an erase electric field applied to the first portion 150a. Thereby, a polarization direction of the first portion 150a may be switched by the program electric field EP, while the polarization direction of the first portion 150a may be maintained without switching by the read electric field ER or the erase electric field the second portion 150b.

The second portion 150b that is close to the second side surface 1502 to which a relatively small electric field is applied may have the relatively small second coercive electric field E2. In this instance, the second coercive electric field E2 may be less than a program electric field EP applied to the second portion 150b, and be greater than a read electric field ER or an erase electric field applied to the second portion 150b. Thereby, a polarization direction of the second portion 150b may be switched by the program electric field EP, while the polarization direction of the second portion 150b may be maintained without switching by the read electric field ER or the erase electric field the second portion 150b.

The third portion 150c may have a coercive electric field (e.g., the third coercive electric field E3) that is greater than the first coercive electric field E1 and is smaller than the second coercive electric field E2. In this instance, the coercive electric field (e.g., the third coercive electric field E3) of the third portion 105c may be less than a program electric field EP applied to the third portion 150cb, and be greater than a read electric field ER or an erase electric field applied to the third portion 150c. Thereby, the polarization direction of the third portion 150c may be switched by the program electric field EP, while the polarization direction of the third portion 150c may be maintained without switching by the read electric field ER or the erase electric field.

In an embodiment, an entire portion of the ferroelectric layer 150 in a region that corresponds to one gate electrode 130 (e.g., an entire portion from the first side surface 1501 of the ferroelectric layer 150 to the second side surface 1502 of the ferroelectric layer 150 in the region that corresponds to one gate electrode 130) may have a coercive electric field that is less than a program electric field EP and greater than a read electric field ER or an erase electric field. Thereby, the entire portion of the ferroelectric layer 150 may have the same polarization direction by the program electric field EP, the read electric field ER, or the erase electric field.

Accordingly, in an embodiment, a polarization direction of a memory cell selected in the program operation may be switched to have a desirable polarization direction, and a polarization direction of an unselected memory cell may be prevented from undesirably switching in the read operation or the erase operation.

In a comparative example where an entire portion of a ferroelectric layer corresponding to a gate electrode, has a second coercive electric field E2, a first region A1 where a read electric field ER or an erase electric field is greater than the second coercive electric field E2 may exist at a side of a first side surface of the ferroelectric layer. Thereby, a disturbance phenomenon where a polarization direction of an unselected memory cell in the first region A1 is undesirably switched by the read electric field ER or the erase electric field may occur. When the ferroelectric layer is included, a threshold voltage of the erase operation is greater than a threshold voltage of the program operation, and thus, the disturbance phenomenon may easily occur.

In another comparative example where an entire portion of a ferroelectric layer corresponding to a gate electrode has a first coercive electric field E1, a second region A2 where a program electric field EP is less than the first coercive electric field E1 may exist at a side of a second side surface of the ferroelectric layer. An under-program phenomenon where a polarization direction of a selected memory cell in the second region A1 is not switched by the program electric field EP, may occur.

In an embodiment, a remnant polarization Pr in the first portion 150a may be less than a remnant polarization Pr in the second portion 150b. A remnant polarization Pr in the third portion 150c may be greater than the remnant polarization Pr in the first portion 150a and be less than the remnant polarization Pr in the second portion 150b. A dielectric constant in the first portion 150a may be greater than a dielectric constant in the second portion 150b. A dielectric constant in the third portion 150c may be less than the dielectric constant in the first portion 150a and be greater than the dielectric constant in the second portion 150b.

For example, each of the first portion 150a and the third portion 150c may include a dopant, and the second portion 150b might not include a dopant. In this instance, a dopant concentration in the first portion 150a may be greater than a dopant concentration in the third portion 150c. In some embodiments, a dopant concentration in the first portion 150a may be greater than a dopant concentration in the second portion 150b. A dopant concentration in the third portion 150c may be less than a dopant concentration in the first portion 150a and may be greater than the dopant concentration in the second portion 150b.

A first grain size in the first portion 150a may be less than a second grain size in the second portion 150b. A third grain size in the third portion 150c may be greater than the first grain size in the first portion 150a and be less than the second grain size in the second portion 150b.

When a relationship that the first coercive electric field E1 of the first portion 150a is greater than the second coercive electric field E2 of the second portion 150b is satisfied, a fraction of at least one of an orthorhombic phase, a tetragonal phase, or a monoclinic phase in the first portion 150a may be the same as or different from a fraction of at least one of an orthorhombic phase, a tetragonal phase, or a monoclinic phase in the second portion 150b. When a relationship that the coercive electric field (e.g., the third coercive electric field E3) of the third portion 150b is less than the first coercive electric field E1 of the first portion 150a is satisfied, a fraction of at least one of an orthorhombic phase, a tetragonal phase, or a monoclinic phase in the third portion 150c may be the same as or different from the fraction of at least one of the orthorhombic phase, the tetragonal phase, or the monoclinic phase in the first portion 150a. When a relationship that the coercive electric field (e.g., the third coercive electric field E3) of the third portion 150b is greater than the second coercive electric field E2 of the second portion 150b is satisfied, the fraction of at least one of the orthorhombic phase, the tetragonal phase, or the monoclinic phase in the third portion 150c may be the same as or different from the fraction of at least one of the orthorhombic phase, the tetragonal phase, or the monoclinic phase in the second portion 150b.

In an embodiment, the first portion 150a, the second portion 150b, and the third portion 150c may be different from one another in one or more of remnant polarization, dielectric constant, material, composition (e.g., dopant concentration), grain size, or crystal structure. The first coercive electric field E1 of the first portion 150a may be greater than the coercive electric field (e.g., the third coercive electric field E3) of the third portion 150c, and the coercive electric field (e.g., the third coercive electric field E3) of the third portion 150c may be greater than the second coercive electric field E2 of the second portion 150b.

In an embodiment, a thickness of the first portion 150a may be greater than a thickness of the second portion 150b. A problem caused by the disturbance phenomenon may be effectively prevented when the disturbance phenomenon is more of a problem than the under-program phenomenon or a problem caused by the under-program phenomenon does not need to be seriously considered. In some embodiments, a thickness of the first portion 150a may be less than a thickness of the second portion 150b. Thereby, a problem caused by the under-program phenomenon may be effectively prevented when the under-program phenomenon is more of a problem than the disturbance phenomenon or a problem caused by the disturbance phenomenon does not need to be seriously considered. In some embodiments, a thickness of the first portion 150a may be the same as a thickness of the second portion 150b.

For example, the thickness of the first portion 150a or the thickness of the second portion 150b may be greater than a thickness of the third portion 150c to effectively prevent the problem caused by the disturbance phenomenon and/or the under-program phenomenon. However, the embodiments are not limited thereto. In some embodiments, the thickness of the first portion 150a or the thickness of the second portion 150b may be the same as or less than a thickness of the third portion 150c. When the third portion 150c has a uniform coercive electric field (e.g., the third coercive electric field E3), the third portion 150c that has the uniform coercive electric field may have a relatively thickness and thus the ferroelectric layer 150 may be formed by an easy manufacturing process.

However, the embodiments are not limited thereto. Accordingly, the thickness of the first portion 150a, the thickness of the second portion 150b, and/or the thickness of the third portion 150c may be modified. For example, considering a pattern or a shape of the program electric field EP, the read electric field ER, or the erase electric field in the ferroelectric layer 150 from the first side surface 1501 to the second side surface 1502, the thickness of the first portion 150a, the thickness of the second portion 150b, and/or the thickness of the third portion 150c may be adjusted.

A manufacturing method of a semiconductor device 10 according to example embodiments will be briefly described.

A plurality of sacrificial insulation layers and a plurality of cell insulation layers 132 may be alternately formed to form a stacking structure on a second substrate 110. The sacrificial insulation layer may include or be formed of a material that is different from a material of the cell insulation layer 132 (e.g., an interlayer insulation layer 132m). For example, the sacrificial insulation layer may include or be formed of silicon, silicon oxide, silicon carbide, silicon nitride, or so on, which is different from the material of the cell insulation layer 132 (e.g., the interlayer insulation layer 132m).

A penetration portion may be formed, at least at a portion of a cell array region 102, to correspond to a channel structure CH. A ferroelectric layer 150, a first interfacial insulation layer 152a, a channel layer 140, a core insulation layer 142, a channel pad 144, or other components, may be formed in the penetration portion to form the channel structure CH.

The ferroelectric layer 150 that includes a first side surface 1501 and a second side surface 1502 having different properties or physical properties may be formed by any of various methods. In this instance, the ferroelectric layer 150 may be formed by a deposition process (e.g., an atomic layer deposition process). The ferroelectric layer 150 that includes the first side surface 1501 and the second side surface 1502 having different properties or physical properties may be formed by adjusting a process condition in the deposition process. For example, materials or compositions in the first side surface 1501 and the second side surface 1502 of the ferroelectric layer 150 may be varied by adjusting gas atmosphere, deposition time, a deposition order, deposition temperature, or so on in the deposition process. In non-limiting embodiments, grain sizes in the first side surface 1501 and the second side surface 1502 of the ferroelectric layer 150 may be varied by adjusting gas atmosphere, deposition time, a deposition order, deposition temperature, or so on in the deposition process, or by adjusting time, temperature, gas atmosphere, or so on in a heat-treatment process that is separately performed from the deposition process. In some embodiments, crystal structures (e.g., fractions of the phases or the crystal structures) in the first side surface 1501 and the second side surface 1502 of the ferroelectric layer 150 may be varied by adjusting materials or compositions of the ferroelectric layer 150, or gas atmosphere, deposition time, a deposition order, deposition temperature, or so on in the deposition process, or by adjusting time, temperature, gas atmosphere, or so on in the heat-treatment process that is separately performed from the deposition process. However, the embodiments are not limited thereto. The ferroelectric layer 150 that includes the first side surface 1501 and the second side surface 1502 having different properties or physical properties may be formed by any of various methods.

A penetration region that corresponds to a separation structure 146 may be formed in the stacking structure and the sacrificial insulation layers may be removed through the penetration region. The gate electrodes 130 may be formed in portions where the sacrificial insulation layers are removed to form a gate stacking structure 120. The separation structure 146 may be formed, for example, by filling an insulating or other material in the penetration region. Thereby, a cell region 100 may be formed.

An operation method of a semiconductor device 10 (e.g., a ferroelectric memory device) will be described in more detail with reference to FIG. 3. The semiconductor device 10 (e.g., the ferroelectric memory device) may include a gate stacking structure 120 that includes a gate electrode 130 and a channel structure CH including a ferroelectric layer 150. In a right enlarged portion of FIG. 3, a polarization direction of the ferroelectric layer 150 in a program operation is illustrated.

Referring to FIG. 3, in a program operation, voltages may be applied to the gate electrode 130, the channel layer 140, or other components, so that a first portion P1 of the ferroelectric layer 150 that corresponds to a selected gate electrode 130m has a first polarization state and a second portion P2 of the ferroelectric layer 150 that corresponds to an unselected gate electrode 130n has a second polarization state. In the first portion P1 that has the first polarization state, positive charges may be accumulated to be close to the channel layer 140, and negative charges may be disposed far away from the channel layer 140. Accordingly, a selected transistor that includes the selected gate electrode 130m may have a relatively low threshold voltage. In the second portion P2 that has the second polarization state, negative charges may be accumulated to be close to the channel layer 140, and positive charges may be disposed far away from the channel layer 140. Accordingly, an unselected transistor that includes the unselected gate electrode 130n may have a relatively high threshold voltage.

In a read operation, a current that flows through the channel layer 140 in the selected transistor and a current that flows through the channel layer 140 in the unselected transistor may be different from one another by a difference between the threshold voltage in first polarization state and the threshold voltage in the second polarization state. Accordingly, the selected transistor and the unselected transistor may be determined or distinguished by using the difference in current that flows through the channel layer 140. In this instance, the selected transistor that has the first polarization state may have the relatively low threshold voltage and thus a relatively large amount of a current may flow through the selected transistor, while the unselected transistor that has the second polarization state may have the relatively high threshold voltage and thus a relatively low amount of a current may flow through the unselected transistor.

In an erase operation, voltages may be applied to the gate electrode 130, the channel layer 140, or other components, so that portions of the ferroelectric layer 150 that correspond to the gate electrodes 130, respectively, have the second polarization state.

The semiconductor device 10 that includes the channel structure CH including the ferroelectric layer 150 may maintain data without an externally applied electric field, have a relatively low operating voltage, and have a fast operating speed.

According to an embodiment, the first side surface 1501 and the second side surface 1502 of the ferroelectric layer 150 may have different properties or different mechanical properties, and thus, a performance deterioration that may occur due to undesirable phenomena (e.g., the disturbance phenomenon or the under-program phenomenon) in the operation of the semiconductor device 10 may be prevented. More particularly, in the semiconductor device 10 that includes the ferroelectric layer 150 and has a vertical structure or a 3-dimensional structure and may have an electric field difference due to an electric field concentration, the performance deterioration in the operation of the semiconductor device 10 may be prevented. Accordingly, the performance of the semiconductor device 10 may be enhanced.

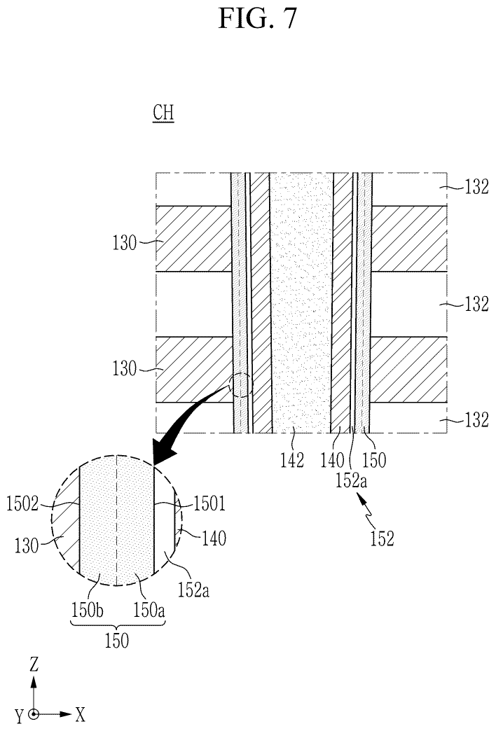

Hereinafter, referring to FIG. 7 to FIG. 14, semiconductor devices according to embodiments will be described in detail. To the extent that an element is not described in detail, it may be understood that the element is at least substantially similar to (and/or the same as) a corresponding element that has been described elsewhere within the present disclosure.

FIG. 7 is a partial cross-sectional view that illustrates a portion of a memory cell structure included in a semiconductor device according to an embodiment. FIG. 7 illustrates a portion that corresponds to FIG. 3.

Referring to FIG. 7, in an embodiment, a ferroelectric layer 150 may have a two-layered structure. The ferroelectric layer 150 or the two-layered structure may include a first portion 150a that includes a first side surface 1501 and a second portion 150b that includes a second side surface 1502. The description with reference to FIG. 1 to FIG. 6 may be applied as is, except that the ferroelectric layer 150 in these example embodiments, includes the first portion 150a and the second portion 150b and does not include a third portion 150c (refer to FIG. 3). By the two-layered structure of the ferroelectric layer 150 that includes the first portion 150a and the second portion 150b, a problem caused by an electric field concentration may be prevented and a semiconductor device or the ferroelectric layer 150 may have a simple structure.

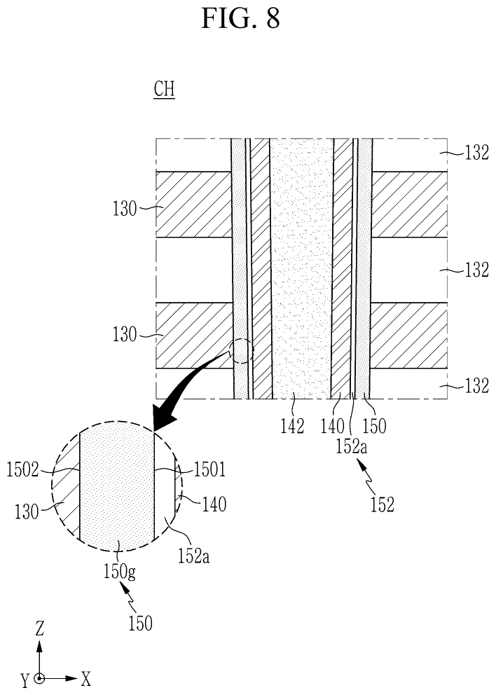

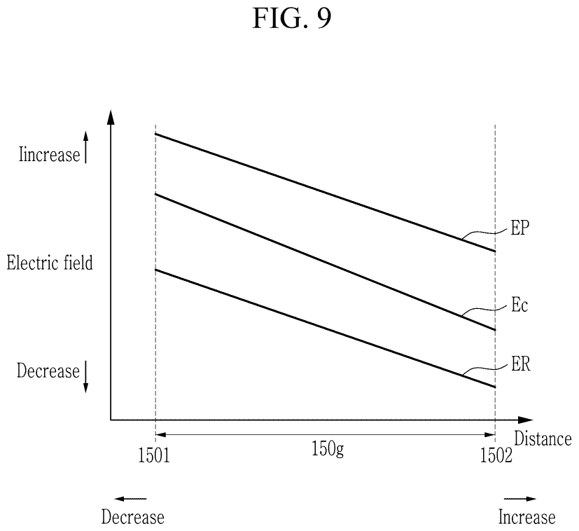

FIG. 8 is a partial cross-sectional view that illustrates a portion of a memory cell structure included in a semiconductor device according to an embodiment. FIG. 9 is a graph that illustrates an electric field in a ferroelectric layer according to a distance from a center of a channel structure included in the semiconductor device illustrated in FIG. 8. FIG. 8 illustrates a portion that corresponds to FIG. 3, and FIG. 9 illustrates a portion that corresponds to FIG. 6,

Referring to FIG. 8 and FIG. 9, in an embodiment, at least a portion of a ferroelectric layer 150 may include a gradually changed portion 150g. In the gradually changed portion 150g, a material or a property may be gradually changed from a portion spanning between a first side surface 1501 and a second side surface 1502. For example, in the gradually changed portion 150g, at least one property of a material, a composition, a grain size, a crystal structure (e.g., a fraction of a crystal structure), or a coercive electric field changes from the first side surface to the second side surface. In this instance, in the gradually changed portion 150g, a remnant polarization or a dielectric constant may be gradually changed.

In an embodiment, in the gradually changed portion 150g, the coercive electric field may gradually decrease from the portion that is close to the first side surface 1501 of the ferroelectric layer 150 toward the portion that is close to the second side surface 1502 of the ferroelectric layer 150. In the gradually changed portion 150g, the remnant polarization may gradually increase from the portion that is close to the first side surface 1501 of the ferroelectric layer 150 toward the portion that is close to the second side surface 1502 of the ferroelectric layer 150. In the gradually changed portion 150g, the dielectric constant may gradually decrease from the portion that is close to the first side surface 1501 of the ferroelectric layer 150 toward the portion that is close to the second side surface 1502 of the ferroelectric layer 150.

In the gradually changed portion 150g, a dopant concentration may gradually decrease from the portion that is close to the first side surface 1501 of the ferroelectric layer 150 toward the portion that is close to the second side surface 1502 of the ferroelectric layer 150. In this instance, the second side surface 1502 may include a dopant or might not include the dopant.

In an embodiment, in the gradually changed portion 150g, the grain size may gradually decrease from the portion that is close to the first side surface 1501 of the ferroelectric layer 150 toward the portion that is close to the second side surface 1502 of the ferroelectric layer 150.

In an embodiment, in the gradually changed portion 150g, a fraction of at least one of an orthorhombic phase, a tetragonal phase, or a monoclinic phase may gradually increase or decrease from the portion that is close to the first side surface 1501 of the ferroelectric layer 150 toward the portion that is close to the second side surface 1502 of the ferroelectric layer 150.

In an embodiment, one or more of the remnant polarization, the dielectric constant, the material, the composition (e.g., the dopant concentration), the grain size, or the crystal structure may be gradually changed in the gradually changed portion 150g, and a coercive electric field of the first side surface 1501 of the ferroelectric layer 150 may be greater than a coercive electric field of the second side surface 1502 of the ferro electric layer 150.

In FIG. 8 illustrates as an example that the gradually changed portion 150g is disposed at the first side surface 1501 and the second side surface 1502 and between the first side surface 1501 and the second side surface 1502 in a portion of the ferroelectric layer 150. However, the present embodiments are not limited thereto. In some embodiments, a portion of the ferroelectric layer 150 may include the gradually changed portion 150g. For example, at least one of the first portion 150a, the second portion 150b, or the third portion 150c in FIG. 3 or at least one of the first portion 150a or the second portion 150b in FIG. 7 may be the gradually changed portion 150g.

FIG. 8 illustrates as an example that the coercive electric field gradually changes in the gradually changed portion 150g to have a linear shape, but the embodiments are not limited thereto. In the gradually changed portion 150g, the coercive electric field may be changed to have various patterns or shapes.

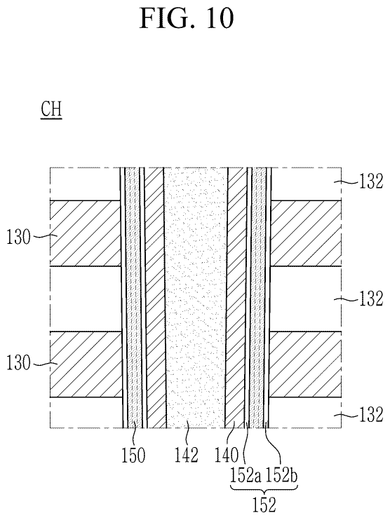

FIG. 10 is a partial cross-sectional view that illustrates a portion of a memory cell structure included in a semiconductor device according to an embodiment. FIG. 10 illustrates a portion that corresponds to FIG. 3.

Referring to FIG. 10, in an embodiment, an interfacial insulation layer 152 may include a first interfacial insulation layer 152a and a second interfacial insulation layer 152b.

The first interfacial insulation layer 152a may extend in an extension direction of a channel structure CH or a vertical direction (a z-axis direction in the drawings) between a ferroelectric layer 150 and a channel layer 140. The second interfacial insulation layer 152b may extend in the extension direction of the channel structure CH or the vertical direction (the z-axis direction in the drawings) between gate electrodes 130 and the ferroelectric layer 150. FIG. 10 illustrates as an example that the interfacial insulation layer 152 includes the first interfacial insulation layer 152a and the second interfacial insulation layer 152b, but the embodiments are not limited thereto. For example, the interfacial insulation layer 152 may include at least one of the first or second interfacial insulation layer 152a or 152b.

FIG. 10 illustrates as an example that the ferroelectric layer 150 has a structure illustrated in FIG. 3, but the embodiments are not limited thereto. The ferroelectric layer 150 may have a structure in embodiments or modified embodiments described with reference to FIG. 3, FIG. 7 to FIG. 9.

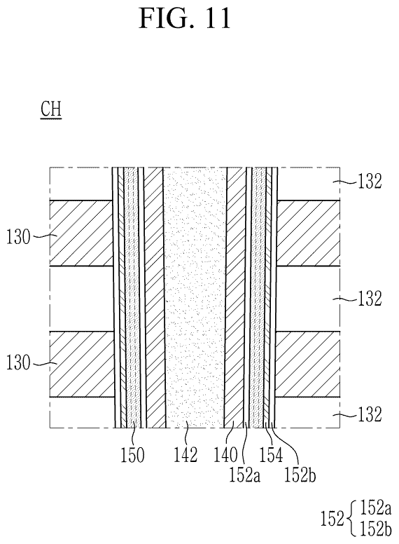

FIG. 11 is a partial cross-sectional view that illustrates a portion of a memory cell structure included in a semiconductor device according to an embodiment. FIG. 11 illustrates a portion that corresponds to FIG. 3.

Referring to FIG. 11, in an embodiment, an interfacial insulation layer 152 may include a first interfacial insulation layer 152a and a second interfacial insulation layer 152b, and a channel structure CH may further include a charge trap layer 154 that is disposed between the second interfacial insulation layer 152b and a ferroelectric layer 150. The charge trap layer 154 may extend in an extension direction of the channel structure CH or a vertical direction (a z-axis direction in the drawings) between the second interfacial insulation layer 152b and the ferroelectric layer 150. The description with reference to FIG. 1 to FIG. 6, and FIG. 11 may be applied to the first interfacial insulation layer 152a and the second interfacial insulation layer 152b as is.

The charge trap layer 154 may include or be formed of at least one of silicon oxide (SiOx), silicon nitride (SiNx), silicon oxynitride (SiONx), aluminum oxide (AlOx), hafnium oxide (HfOx), or a nano crystal, or a combination thereof. For example, the charge trap layer 154 may include or be formed of at least one of SiOx, SiNx, SiONx, a stacked structure of SiOx/SiNx, a stacked structure of SiOx/SiONx, a stacked structure of SiOx/AlOx, a stacked structure of SiOx/HfOx, a stacked structure of SiOx/SiNx/SiOx, or a stacked structure of SiOx/a nano crystal. However, the embodiments are not limited thereto, and the charge trap layer 154 may include any of various materials.

FIG. 11 illustrates as an example that the ferroelectric layer 150 has a structure illustrated in FIG. 3, but the embodiments are not limited thereto. The ferroelectric layer 150 may have a structure in embodiments or modified embodiments described with reference to FIG. 3, FIG. 7 to FIG. 9.

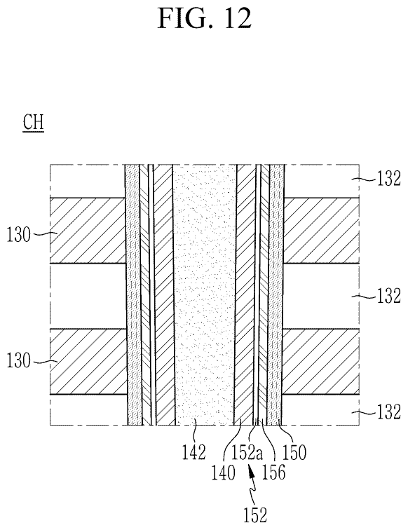

FIG. 12 is a partial cross-sectional view that illustrates a portion of a memory cell structure included in a semiconductor device according to an embodiment. FIG. 12 illustrates a portion that corresponds to FIG. 3.

Referring to FIG. 12, in an embodiment, a floating electrode 156 that is disposed between a ferroelectric layer 150 and a first interfacial insulation layer 152a may be further included. The floating electrode 156 may extend in an extension direction of a channel structure CH or a vertical direction (a z-axis direction in the drawings) between the ferroelectric layer 150 and the first interfacial insulation layer 152a. The floating electrode 156 may refer to an electrode to which no voltage is applied in a program operation, a read operation, an erase operation, or other operation. The floating electrode 156 may compensate for a polarization charge of the ferroelectric layer 150, thereby preventing depolarization.

The floating electrode 156 may include any of various conductive materials. For example, the floating electrode 156 may include or be formed of a metal (e.g., refractory metal) (such as, tungsten (W), copper (Cu), aluminum (Al), molybdenum (Mo), niobium (Nb), or other metals), polycrystalline silicon (e.g., doped or undoped polycrystalline silicon), metal nitride, a barrier metal (e.g., titanium nitride (TiN), tantalum nitride (TaN), tungsten nitride (WN), or others), or combination thereof.

FIG. 12 illustrates as an example that the ferroelectric layer 150 has a structure illustrated in FIG. 3, but the embodiments are not limited thereto. The ferroelectric layer 150 may have a structure in embodiments or modified embodiments described with reference to FIG. 3, FIG. 7 to FIG. 9. FIG. 12 illustrates as an example that the interfacial insulation layer 152 includes the first interfacial insulation layer 152a, but the embodiments are not limited thereto. For example, the interfacial insulation layer 152 may include at least one of a first or second interfacial insulation layer 152a or 152b (refer to FIG. 10 or FIG. 11).

FIG. 13 is a partial cross-sectional view that illustrates a portion of a memory cell structure included in a semiconductor device according to an embodiment. FIG. 13 illustrates a portion that corresponds to FIG. 3.

Referring to FIG. 13, in an embodiment, a ferroelectric layer 150 may be partially disposed between two cell insulation layers 132 (e.g. two interlayer insulation layers) that are adjacent to one another to correspond to a portion where a gate electrode 130 is provided. By the ferroelectric layer 150 that is partially disposed to correspond to each gate electrode 130, interference between adjacent gate electrodes 130 may be minimized.

In FIG. 13, it is illustrated as an example that the ferroelectric layer 150 has a structure illustrated in FIG. 3, but the embodiments are not limited thereto. The ferroelectric layer 150 may have a structure in embodiments or modified embodiments described with reference to FIG. 3, FIG. 7 to FIG. 9.

In FIG. 13, it is illustrated as an example that a channel structure CH has a structure illustrated in FIG. 3, but the embodiments are not limited thereto. The channel structure CH may have a structure in embodiments or modified embodiments described with reference to FIG. 3, FIG. 10 to FIG. 12. In this instance, at least one of the ferroelectric layers 150, a first interfacial insulation layer 152a, a second interfacial insulation layer 152b (refer to FIG. 10 or FIG. 11), or a floating electrode 156 (refer to FIG. 12) may be partially disposed between two cell insulation layers 132 that are adjacent to one another to correspond to the portion where the gate electrode 130 is provided.

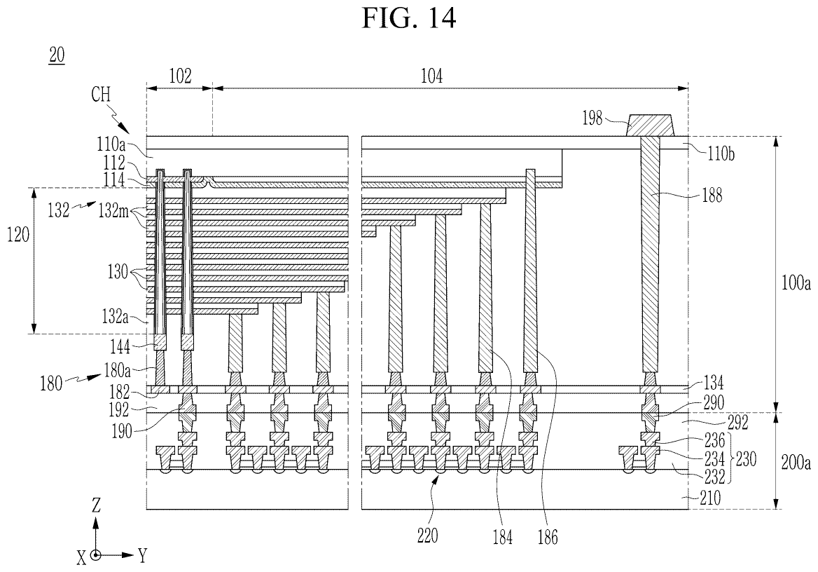

FIG. 14 is a cross-sectional view that schematically illustrates a semiconductor device 20 according to an embodiment.

Referring to FIG. 14, a semiconductor device 20 according to an embodiment may be a bonding semiconductor device that is formed by forming a cell region 100a through a process that is separately performed from a circuit region 200a and bonding the cell region 100a to the circuit region 200a. For example, the circuit region 200a and the cell region 100a may be bonded by using a hybrid bonding type. The circuit region 200a and the cell region 100a may be bonded by a chip to chip (C2C) bonding process, a chip-to-wafer bonding process, or a wafer-to-wafer bonding process.

The circuit region 200a may include a first substrate 210, a circuit element 220, a first wiring portion 230, and a first bonding structure 290 that is electrically connected to the first wiring portion 230 and is positioned at a surface facing the cell region 100a. A peripheral area of the first bonding structure 290 at the surface of the circuit region 200a may be covered by a first bonding insulation layer 292.

The cell region 100a may include a second substrate 110, a gate stacking structure 120, a channel structure CH, a second wiring portion 180, and a second bonding structure 190 that is electrically connected to the second wiring portion 180 and is positioned at a surface facing the circuit region 200a. A peripheral area of the second bonding structure 190 may be covered by a second bonding insulation layer 192.

In an embodiment, the second substrate 110a may be a semiconductor substrate that includes a semiconductor material. For example, the second substrate 110a may be a semiconductor substrate that includes or is formed of a semiconductor material, or may be a semiconductor substrate in which a semiconductor layer is on a base substrate. For example, the second substrate 110a may include or be formed of single-crystalline or polycrystalline silicon, germanium, silicon-germanium, silicon-on-insulator, germanium-on-insulator, and the like. In some embodiments, the second substrate 110a may include a supporting member that includes an insulation layer or an insulating material. This is because a semiconductor substrate that is provided in the cell region 100a may be removed after the cell region 100a is bonded to the circuit region 200a and the supporting member that includes the insulation layer or the insulating material may be formed.

In an embodiment, the gate stacking structure 120 may be sequentially stacked on a lower portion of the second substrate 110a in the drawing, and may have a structure in which a gate stacking structure 120 illustrated in FIG. 1 is disposed in a vertically inverted manner. A channel structure CH that passes through the gate stacking structure 120 may have a structure in which a channel structure CH illustrated in FIG. 2 is disposed in a vertically inverted manner. Accordingly, in a cross-sectional view, the channel structure CH may have an inclined side surface such that a width of the channel structure CH decreases from the circuit region 200a toward the second substrate 110a. A channel pad 144 and the second wiring portion 180 disposed at an upper portion of the gate stacking structure 120 may be adjacent to the circuit region 200a.

In an embodiment, an input/output connection wiring 188 may be electrically connected to a part of second bonding structures 190. For example, the input/output pad 198 may be disposed on an outer insulation layer 110b that is disposed on an outer surface of the second substrate 110a. In some embodiments, an additional input/output pad that is electrically connected to the circuit region 200a may be provided. In some embodiments, an insulation layer that covers a portion of the input/output pad 198 may be further included.

In FIG. 14, it is illustrated as an example that the gate stacking structure 120 includes one stacking portion. In some embodiments, the gate stacking structure 120 may include two or more stacking portions. Unless otherwise described, the description of a gate stacking structure 120 and a channel structure CH with reference to FIG. 1 and FIG. 2 may be applied as is. In FIG. 14, it is illustrated as an example that an electrical connection structure of the channel structure CH with horizontal conductive layers 112 and 114 and/or the second substrate 110a is the same as an electrical connection structure of a channel structure CH with horizontal conductive layers 112 and 114 and/or a second substrate 110 in FIG. 1. The embodiments are not limited thereto, and the electrical connection structure of the channel structure CH with the horizontal conductive layers 112 and 114 and/or the second substrate 110a may be variously modified.

The circuit region 200a and the cell region 100a may be bonded by hybrid bonding. More particularly, the circuit region 200a and the cell region 100a may be bonded by the hybrid bonding including metal bonding between the first bonding structure 290 and the second bonding structure 190 and insulation-layer bonding between the first bonding insulation layer 292 and the second bonding insulation layer 192.

For example, the first boding structure 290 and/or the second bonding structure 190 may include at least one of copper, aluminum, tungsten, nickel, gold, tin, manganese, cobalt, titanium, tantalum, ruthenium, or beryllium, or an alloy including the same. For example, the first and second bonding structures 290 and 190 may include copper so that the cell region 100a and the circuit region 200a may be bonded (e.g., directly bonded) to one another by copper-to-copper bonding.

For example, at an insulation-layer bonding surface, the first bonding insulation layer 292 and the second bonding insulation layer 192 may include the same insulating material. For example, the first bonding insulation layer 292 and/or the second bonding insulation layer 192 may include a layer that includes silicon carbonitride at least at the bonding surface. However, the embodiments are not limited thereto. The first boding insulation layer 292 and/or the second bonding insulation layer 192 may include a material the same as or a different from a material that is included in a cell insulation layer 132 or an additional insulation layer 134 of the cell region 100a or an insulation layer 232 of the circuit region 200a.

In an embodiment, by the second wiring portion 180, the second bonding structure 190, the first bonding structure 290, and the first wiring portion 230, a bit line 182 that is connected to the channel structure CH, a gate electrode 130, the second substrate 110a, and/or the horizontal conductive layers 112 and 114 may be electrically connected to the circuit element 220 of the circuit region 200a.

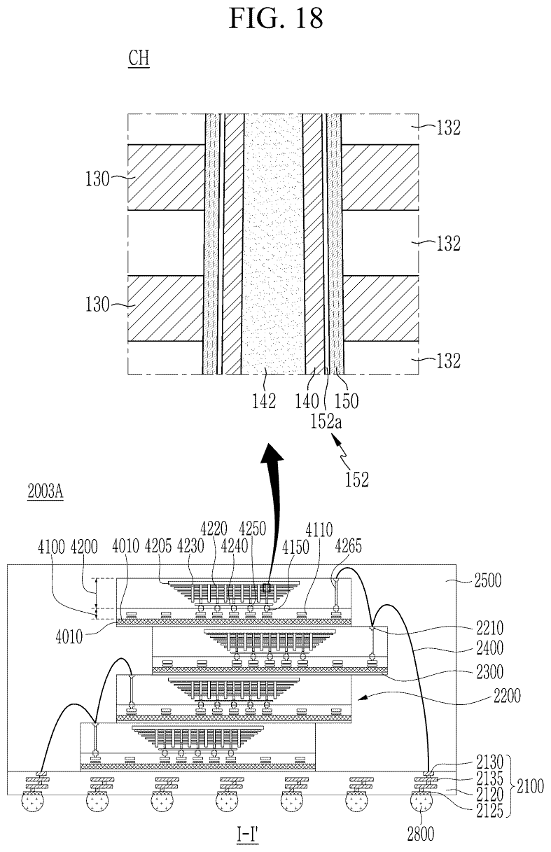

For example, the circuit region 200a and the cell region 100a may correspond to a first structure 1100F and a second structure 1100S of a semiconductor device 1100 that is included in an electronic system 1000 illustrated in FIG. 15, respectively. For example, the circuit region 200a and the cell region 100a may be regions that include a first structure 4100 and a second structure 4200 of a semiconductor chip 2200a illustrated in FIG. 18, respectively.

Hereinafter, an example of an electronic system that includes a semiconductor device described in the above will be described in detail.

FIG. 15 schematically illustrates an electronic system that includes a semiconductor device according to an embodiment.

Referring to FIG. 15, an electronic system 1000 according to example embodiments may include a semiconductor device 1100 and a controller 1200 that is electrically connected to the semiconductor device 1100. The electronic system 1000 may be a storage device that includes one or a plurality of semiconductor devices 1100 or an electronic device that includes the storage device. For example, the electronic system 1000 may be a solid-state drive (SSD) device, a universal serial bus (USB), a computing system, a medical device, or a communication device that includes one or a plurality of semiconductor devices 1100.

The semiconductor device 1100 may be a non-volatile memory device, and for example, may be a NAND flash memory device described with reference to FIG. 1 to FIG. 14. The semiconductor device 1100 may include a first structure 1100F and a second structure 1100S that is disposed on the first structure 1100F. In some embodiments, the first structure 1100F may be next to the second structure 1100S. The first structure 1100F may be a peripheral circuit structure that includes a decoder circuit 1110, a page buffer 1120, and a logic circuit 1130. The second structure 1100S may be a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, as shown in FIG. 15, each of memory cell strings CSTR may include lower transistors LT1 and LT2 that are adjacent to the common source line CSL, upper transistors UT1 and UT2 that are adjacent to the bit line BL, and a plurality of memory cell transistors MCT between the lower transistors LT1 and LT2 and the upper transistors UT1 and UT2. A number of the lower transistors LT1 and LT2 and a number of the upper transistors UT1 and UT2 may be variously modified according to an embodiment.

In an embodiment, the lower transistor LT1 or LT2 may include a ground selection transistor, and the upper transistor UT1 or UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wiring 1115 that extends to the second structure 1100S within the first structure 1100F. The bit line BL may be electrically connected to the page buffer 1120 through a second connection wiring 1125 that extends to the second structure 1100S within the first structure 1100F.

In the first structure 1100F, the decoder circuit 1110 and the page buffer 1120 may execute a control operation for at least one memory cell transistor selected from the plurality of memory cell transistors MCT. The decoder circuit 1110 and the page buffer 1120 may be controlled by the logic circuit 1130. The semiconductor device 1100 may communicate with the controller 1200 through an input/output pad 1101 that is electrically connected to the logic circuit 1130. The input/output pad 1101 may be electrically connected to the logic circuit 1130 through an input/output connection wiring 1135 that extends to the second structure 1100S within the first structure 1100F.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, may be transmitted through the NAND interface 1221. The host interface 1230 may provide a communication function between the electronic system 1000 and an external host. When a control command is received from the external host through the host interface 1230, the processor 1210 may control the semiconductor device 1100 in response to the control command.

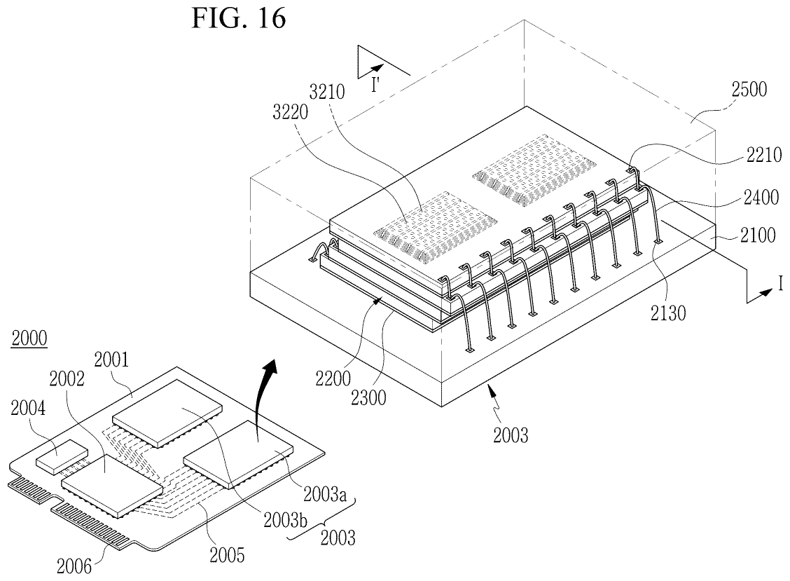

FIG. 16 is a perspective view that schematically illustrates an electronic system including a semiconductor device according to an example embodiment.

Referring to FIG. 16, an electronic system 2000 according to an example embodiment may include a main substrate 2001, a controller 2002 that is mounted on the main substrate 2001, one or more semiconductor packages 2003, and a DRAM 2004. The semiconductor package 2003 and the DRAM 2004 may be connected to the controller 2002 through a wiring pattern 2005 that is provided on the main substrate 2001.

The main substrate 2001 may include a connector 2006 that includes a plurality of pins coupled to the external host. A number and an arrangement of the plurality of pins in the connector 2006 may vary depending on a communication interface between the electronic system 2000 and the external host. In an embodiment, the electronic system 2000 may communicate with the external host according to any one of interfaces such as a universal serial bus (USB), a peripheral component interconnect express (PCI-Express), a serial advanced technology attachment (SATA), or an M-Phy for a universal flash storage (UFS). In an embodiments, the electronic system 2000 may operate by power that is supplied from the external host through the connector 2006. The electronic system 2000 may further include a power management integrated circuit (PMIC) that distributes the power supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating or buffering a speed difference between the semiconductor package 2003, which is a data storage space, and the external host. The DRAM 2004 that is included in the electronic system 2000 may also be a kind of cache memory, and may also provide a space for temporarily storing data in a control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b that are spaced apart from one another. Each of the first and second semiconductor packages 2003a and 2003b may be a semiconductor package that includes a plurality of semiconductor chips 2200. Each of the first and second semiconductor packages 2003a and 2003b may include a package substrate 2100, the semiconductor chip 2200 that is disposed on the package substrate 2100, an adhesive layer 2300 at a lower surface of each semiconductor chip 2200, a connection structure 2400 that electrically connect the semiconductor chip 2200 and the package substrate 2100, and a molding layer 2500 that covers the semiconductor chip 2200 and the connection structure 2400 on the package substrate 2100.

The package substrate 2100 may be a printed circuit board that includes a package upper pad 2130. Each semiconductor chip 2200 may include an input/output pad 2210. The input/output pad 2210 may correspond to an input/output pad 1101 of FIG. 15. Each semiconductor chip 2200 may include a gate stacking structure 3210 and a channel structure 3220. The semiconductor chip 2200 may include or be a semiconductor device described with reference to FIG. 1 to FIG. 14.

In example embodiments, the connection structure 2400 may be a bonding wire that electrically connects the input/output pad 2210 and the package upper pad 2130. Accordingly, in each of the first and second semiconductor packages 2003a and 2003b, the semiconductor chips 2200 may be electrically connected to one another using a bonding wire type, and the semiconductor chip 2200 may be electrically connected to the package upper pad 2130 of the package substrate 2100. According to an embodiment, in each of the first and second semiconductor packages 2003a and 2003b, the semiconductor chips 2200 may be electrically connected to one another by a connection structure that includes a through silicon via (TSV) instead of the connection structure 2400 of the bonding wire type.

In an example embodiment, the controller 2002 and the semiconductor chip 2200 may be included in one package. For example, the controller 2002 and the semiconductor chip 2200 may be mounted on a separate interposer substrate that is different from the main substrate 2001, and the controller 2002 and the semiconductor chip 2200 may be connected to one another by a wiring of the interposer substrate.

FIG. 17 and FIG. 18 are cross-sectional views schematically illustrating semiconductor packages according to embodiments, respectively. FIG. 17 and FIG. 18 respectively illustrate embodiments of the semiconductor package 2003 of FIG. 16, and conceptually illustrate a region of the semiconductor package 2003 taken along a line I-I′ in FIG. 16.

Referring to FIG. 17, in a semiconductor package 2003, a package substrate 2100 may be a printed circuit board. The package substrate 2100 may include a package substrate body portion 2120, a package upper pad 2130 that is disposed at an upper surface of the package substrate body portion 2120, a package lower pad 2125 that is disposed at a lower surface of the package substrate body portion 2120 or is exposed through the lower surface of the package substrate body portion 2120, and an internal wiring 2135 that electrically connects the package upper pad 2130 and the package lower pad 2125 inside the package substrate body portion 2120. The package upper pad 2130 may be electrically connected to the connection structure 2400. The package lower pad 2125 may be connected to a wiring pattern 2005 of a main substrate 2001 of an electronic system 2000, as illustrated in FIG. 16, through a conductive connection portion 2800.

The semiconductor chip 2200 may include a semiconductor substrate 3010, and a first structure 3100 and a second structure 3200 that are sequentially stacked on the semiconductor substrate 3010. The first structure 3100 may include a peripheral circuit region that includes a peripheral wiring 3110. The second structure 3200 may include a common source line 3205, a gate stacking structure 3210 that is disposed on the common source line 3205, a channel structure 3220 and a separation structure 3230 that pass through the gate stacking structure 3210, a bit line 3240 that is electrically connected to the channel structure 3220, and a gate connection wiring that is electrically connected to a word line WL (refer to FIG. 15) of the gate stacking structure 3210.

In the semiconductor chip 2200 or a semiconductor device according to example embodiments, a first side surface and a second side surface of a ferroelectric layer may have different properties or different mechanical properties, and thus, performance of the semiconductor chip 2200 or the semiconductor device may be enhanced.

Each of the semiconductor chips 2200 may include a through wiring 3245 that is electrically connected to the peripheral wiring 3110 of the first structure 3100 and extends into the second structure 3200. The through wiring 3245 may pass through the gate stacking structure 3210, and may be further provided at an outside of the gate stacking structure 3210. Each semiconductor chip 2200 may further include an input/output connection wiring 3265 that is electrically connected to the peripheral wiring 3110 of the first structure 3100 and extend into the second structure 3200, and an input/output pad 2210 that is electrically connected to the input/output connection wiring 3265.

In an example embodiment, in the semiconductor package 2003, a plurality of semiconductor chips 2200 may be electrically connected to one another by a connection structure 2400 having a bonding wire type. In some embodiments, the plurality of semiconductor chips 2200 or a plurality of portions that constitute the plurality of semiconductor chips 2200 may be electrically connected by a connection structure that includes a through silicon via (TSV).

Referring to FIG. 18, in a semiconductor package 2003A, each semiconductor chip 2200a may include a semiconductor substrate 4010, a first structure 4100 that is disposed on the semiconductor substrate 4010, and a second structure 4200 that is disposed on the first structure 4100 and is bonded to the first structure 4100 by a wafer bonding type.

The first structure 4100 may include a peripheral circuit region that includes a peripheral wiring 4110 and a first bonding structure 4150. The second structure 4200 may include a common source line 4205, a gate stacking structure 4210 between the common source line 4205 and the first structure 4100, a channel structure 4220 and a separation structure 4230 that pass through the gate stacking structure 4210, and a second bonding structures 4250 that are electrically connected to the channel structure 4220 and a word line WL (refer to FIG. 15) of the gate stacking structure 4210. For example, the second bonding structure 4250 may be electrically connected to the channel structure 4220 and the word line WL through a bit line 4240 that is electrically connected to the channel structure 4220 and a gate connection wiring that is electrically connected to the word line WL. The first bonding structure 4150 of the first structure 4100 and the second bonding structure 4250 of the second structure 4200 may be in contact with and bonded to one another. For example, portions of the first bonding structure 4150 and the second bonding structure 4250 where the first bonding structure 4150 and the second bonding structure 4250 are bonded may include copper (Cu).

In the semiconductor chip 2200a or a semiconductor device according to an example embodiment, a first side surface and a second side surface of a ferroelectric layer may have different properties or different mechanical properties, and thus, performance of the semiconductor chip 2200a or the semiconductor device may be enhanced.

Each of the semiconductor chips 2200a may further include an input/output pad 2210 and an input/output connection wiring 4265 that is disposed at a lower portion of the input/output pad 2210. The input/output connection wiring 4265 may be electrically connected to a part of the second bonding structures 4250.

In an embodiment, in the semiconductor package 2003A, a plurality of semiconductor chips 2200a may be electrically connected to one another by a connection structure 2400 having a bonding wire type. In some embodiments, the plurality of semiconductor chips 2200a or a plurality of portions that constitute the plurality of semiconductor chips 2200a may be electrically connected by a connection structure that includes a through silicon via (TSV).

While some example embodiments have been described herein, it is to be understood that the disclosure is not limited to the disclosed embodiments, and that the disclosure is intended to cover various modifications and equivalent arrangements included within the spirit and scope of the appended claims.

What is claimed is:

1. A semiconductor device, comprising:
a gate stacking structure that includes a plurality of gate electrodes and a plurality of cell insulation layers, wherein the plurality of gate electrodes and the plurality of cell insulation layers are alternately stacked; and
a channel structure that extends to pass through the gate stacking structure, wherein the channel structure includes a channel layer and a ferroelectric layer,
wherein the ferroelectric layer is between the plurality of gate electrodes and the channel layer and includes a first side surface and a second side surface that are opposite to one another, the first side surface being positioned adjacent to the channel layer and the second side surface being positioned adjacent to a gate electrode among the plurality of gate electrodes, and
wherein the first side surface of the ferroelectric layer and the second side surface of the ferroelectric layer are different from one another in at least one property selected from the group consisting of material, composition, grain size, crystal structure, coercive electric field, remnant polarization, and dielectric constant.

2. The semiconductor device of claim 1, wherein a first distance between a center of the channel structure and the first side surface of the ferroelectric layer is less than a second distance between the center of the channel structure and the second side surface of the ferroelectric layer.

3. The semiconductor device of claim 2, wherein the gate electrode among the plurality of gate electrodes surrounds a circumference of the channel structure.

4. The semiconductor device of claim 2, wherein the first side surface of the ferroelectric layer and the second side surface of the ferroelectric layer have at least one of the following properties with respect to one other:
a coercive electric field of the first side surface of the ferroelectric layer is greater than a coercive electric field of the second side surface of the ferroelectric layer,
a dielectric constant in the first side surface of the ferroelectric layer is greater than a dielectric constant in the second side surface of the ferroelectric layer, and
a remnant polarization in the first side surface of the ferroelectric layer is less than a remnant polarization in the second side surface of the ferroelectric layer.

5. The semiconductor device of claim 2, wherein at least a portion of the ferroelectric layer includes a base material doped with a dopant, and
wherein the first side surface of the ferroelectric layer and the second side surface of the ferroelectric layer are different with respect to at least one of material and dopant concentration in at least one of the following ways:
a material in the first side surface of the ferroelectric layer comprises a first material and the second side surface of the ferroelectric layer comprises a second material, and the first material and the second material are different, or
a first dopant concentration in the first side surface of the ferroelectric layer is greater than a second dopant concentration in the second side surface of the ferroelectric layer.

6. The semiconductor device of claim 2, wherein a first grain size in the first side surface of the ferroelectric layer is smaller than a second grain size in the second side surface of the ferroelectric layer.

7. The semiconductor device of claim 2, wherein the ferroelectric layer includes at least one of an orthorhombic phase, a tetragonal phase, and a monoclinic phase, and
wherein the first side surface of the ferroelectric layer comprises a fraction of at least one phase selected from the group consisting of a first orthorhombic phase, a first tetragonal phase, and a first monoclinic phase, and
wherein the second side surface of the ferroelectric layer comprises a fraction of at least one phase selected from the group consisting of a second orthorhombic phase, a second tetragonal phase, and a second monoclinic phase,
wherein the first side surface and the second side surface are different from one another in fraction of at least one phase selected from the group consisting of the first orthorhombic phase and the second orthorhombic phase, the first tetragonal phase and the second tetragonal phase, and the first monoclinic phase and the second monoclinic phase.

8. The semiconductor device of claim 1, wherein the ferroelectric layer includes a plurality of portions that are different from one another in at least one property selected from the group consisting of material, composition, grain size, crystal structure, and coercive electric field.

9. The semiconductor device of claim 8, wherein the plurality of portions includes a first portion that includes the first side surface, and a second portion that includes the second side surface.

10. The semiconductor device of claim 8, wherein the plurality of portions includes a first portion that includes the first side surface, a second portion that includes the second side surface, and at least one third portion that is disposed between the first portion and the second portion.

11. The semiconductor device of claim 1, wherein at least a portion of the ferroelectric layer includes a gradually changed portion spanning between the first side surface and the second side surface, and
wherein in the gradually changed portion, at least one property selected from the group consisting of a material, a composition, a grain size, a crystal structure, and a coercive electric field, changes from the first side surface to the second side surface.

12. The semiconductor device of claim 1, wherein, in a portion of the semiconductor device that corresponds to one gate electrode among the plurality of gate electrodes, a portion of the ferroelectric layer from the first side surface to the second side surface has a coercive electric field that is less than a program electric field in a program operation and that is greater than a read electric field in a read operation or an erase electric field in an erase operation, and
wherein the portion of the ferroelectric layer has the same polarization direction caused by the program electric field, the read electric field, or the erase electric field.

13. A semiconductor device, comprising:
a gate electrode; and
a channel structure that extends to pass through the gate electrode, wherein the channel structure includes a channel layer and a ferroelectric layer,
wherein the gate electrode surrounds a circumference of the channel structure,
wherein the ferroelectric layer is between the gate electrode and the channel layer and includes a first side surface and a second side surface that are opposite to one another the first side surface being positioned adjacent to the channel layer and the second side surface being positioned adjacent to a gate electrode, and
wherein the first side surface of the ferroelectric layer and the second side surface of the ferroelectric layer are different from one another in coercive electric field.

14. The semiconductor device of claim 13, wherein a first distance between a center of the channel structure and the first side surface of the ferroelectric layer is less than a second distance between the center of the channel structure and the second side surface of the ferroelectric layer.

15. The semiconductor device of claim 14, wherein a coercive electric field of the first side surface of the ferroelectric layer is greater than a coercive electric field of the second side surface of the ferroelectric layer.

16. The semiconductor device of claim 14, wherein the ferroelectric layer includes a first portion and a second portion,
wherein the first portion includes the first side surface and has a first coercive electric field, and
wherein the second portion includes the second side surface and has a second coercive electric field, which second coercive electric field is less than the first coercive electric field.

17. The semiconductor device of claim 14, wherein the ferroelectric layer includes a first portion, a second portion, and at least one third portion,
wherein the first portion includes the first side surface and has a first coercive electric field,
wherein the second portion includes the second side surface and has a second coercive electric field, which second coercive electric field is less than the first coercive electric field, and
wherein the at least one third portion is disposed between the first portion and the second portion, and wherein the at least one third portion has a coercive electric field that is less than the first coercive electric field and is greater than the second coercive electric field.

18. The semiconductor device of claim 13, wherein at least a portion of the ferroelectric layer includes a gradually changed portion spanning from a first portion adjacent to the first side surface to a second portion adjacent to the second side surface, and
wherein in the gradually changed portion, a coercive electric field changes from the first portion adjacent to the first side surface toward the second portion adjacent to the second side surface.

19. The semiconductor device of claim 13, wherein a portion of the ferroelectric layer that corresponds to the gate electrode has a coercive electric field that is less than a program electric field in a program operation, and is greater than a read electric field in a read operation or an erase electric field in an erase operation, and
wherein the portion of the ferroelectric layer has the same polarization direction caused by one of the program electric field, the read electric field, or the erase electric field.

20. An electronic system, comprising:
a main substrate;
a semiconductor device on the main substrate; and
a controller that is disposed on the main substrate and is electrically connected to the semiconductor device,
wherein the semiconductor device comprises:
a gate stacking structure that includes a plurality of gate electrodes and a plurality of cell insulation layers, wherein the plurality of gate electrodes and the plurality of cell insulation layers are alternately stacked; and
a channel structure that extends to pass through the gate stacking structure wherein the channel structure includes a channel layer and a ferroelectric layer,
wherein the ferroelectric layer is between the plurality of gate electrodes and the channel layer and includes a first side surface and a second side surface that are opposite to one another, the first side surface being positioned adjacent to the channel layer and the second side surface being positioned adjacent to a gate electrode among the plurality of gate electrodes, and
wherein the first side surface of the ferroelectric layer and the second side surface of the ferroelectric layer are different from one another in at least one property selected from the group consisting of material, composition, grain size, crystal structure, coercive electric field, remnant polarization, and dielectric constant.
